(19) United States
(12) Patent Application Publication
(10) Pub. No.: US 2025/0063731 A1
(43) Pub. Date: Feb. 20, 2025

(54) SEMICONDUCTOR DEVICE AND ELECTRONIC SYSTEM INCLUDING THE SAME

(71) Applicant: SAMSUNG ELECTRONICS CO., LTD., SUWON-SI (KR)

(72) Inventors: Sangwoo HAN, Suwon-si (KR); Jongho WOO, Suwon-si (KR); Seung Min LEE, Suwon-si (KR); Moonkang CHOI, Suwon-si (KR)

(21) Appl. No.: 18/650,189

(22) Filed: Apr. 30, 2024

(30) Foreign Application Priority Data
Aug. 18, 2023 (KR) 10-2023-0108362

(51) Int. Cl. H10B 43/27; H01L 25/065; H10B 43/10; H10B 43/35; H10B 51/10; H10B 51/20; H10B 80/00

(52) U.S. Cl. CPC H10B 43/27; H01L 25/0652; H10B 43/10; H10B 43/35; H10B 51/10; H10B 51/20; H10B 80/00; H01L 2225/0651

(57) ABSTRACT

A semiconductor device includes a source structure having a first source layer, a second source layer on the first source layer, and a third source layer on the second source layer. A gate stack structure is on the source structure. The gate stack structure includes dielectric patterns and conductive patterns that are alternately stacked. A memory channel structure penetrates the gate stack structure. The memory channel structure includes a channel layer. A data storage layer surrounds the channel layer. A blocking layer surrounds the data storage layer. The second source layer includes an inner sidewall directly contacting the channel layer. The third source layer includes an inner sidewall directly contacting the data storage layer.

### CROSS-REFERENCE TO RELATED APPLICATION

This application claims priority under 35 U.S.C § 119 to Korean Patent Application No. 10-2023-0108362 filed on Aug. 18, 2023 in the Korean Intellectual Property Office, the disclosure of which is incorporated by reference in its entirety herein.

### 1. TECHNICAL FIELD

The present inventive concept relates to a semiconductor device and an electronic system including the same, and more particularly, to a semiconductor device including a third source layer in contact with a data storage layer and an electronic system including the same.

### 2. DISCUSSION OF RELATED ART

Semiconductor devices have an important role in the electronic industry as a result of having a small size, multi-functionality and low fabrication cost. Semiconductor devices may encompass semiconductor memory devices storing logic data, semiconductor logic devices processing operations of logic data, and hybrid semiconductor devices having both memory and logic elements.

Based on an increased consumer demand for electronic products having a high speed and low power consumption, semiconductor devices embedded in the electronic products should have a high operating speed and/or lower operating voltage. However, an increase in integration of semiconductor devices may cause a reduction in electrical properties and production yield for the semiconductor devices. Therefore, research is being conducted concerning increasing the electrical properties and production yield of semiconductor devices.

### SUMMARY

Some embodiments of the present inventive concepts provide a semiconductor device with increased reliability and increased electrical properties and an electronic system including the same.

According to an embodiment of the present disclosure, a semiconductor device includes a source structure having a first source layer, a second source layer on the first source layer, and a third source layer on the second source layer. A gate stack structure is on the source structure. The gate stack structure includes dielectric patterns and conductive patterns that are alternately stacked. A memory channel structure penetrates the gate stack structure. The memory channel structure includes a channel layer. A data storage layer surrounds the channel layer. A blocking layer surrounds the data storage layer. The second source layer includes an inner sidewall directly contacting the channel layer. The third source layer includes an inner sidewall directly contacting the data storage layer.

According to an embodiment of the present disclosure, a semiconductor device includes a source structure having a first source layer, a second source layer on the first source layer, and a third source layer on the second source layer. A gate stack structure is on the source structure. The gate stack structure includes dielectric patterns and conductive patterns that are alternately stacked. A memory channel structure penetrates the gate stack structure. The memory channel structure includes a channel layer. A tunnel dielectric layer surrounds the channel layer. A data storage layer surrounds the tunnel dielectric layer. A blocking layer surrounds the data storage layer. The blocking layer is spaced apart from an upper surface of the second source layer. The second source layer includes a surface directly contacting the tunnel dielectric layer and the data storage layer. The third source layer includes a first top surface directly contacting the blocking layer.

According to an embodiment of the present disclosure, an electronic system includes a main board. A semiconductor device is on the main board. A controller is on the main board. The controller is electrically connected to the semiconductor device. The semiconductor device includes a source structure including a first source layer, a second source layer on the first source layer, and a third source layer on the second source layer. A gate stack structure is on the source structure. The gate stack structure includes dielectric patterns and conductive patterns that are alternately stacked. A memory channel structure penetrates the gate stack structure. A lowermost dielectric pattern of the dielectric patterns is a lower dielectric pattern. The lower dielectric pattern directly contacts the third source layer. The memory channel structure includes a dielectric capping layer. A channel layer surrounds the dielectric capping layer. A tunnel dielectric layer surrounds the channel layer. A data storage layer surrounds the tunnel dielectric layer. A blocking layer surrounds the data storage layer. The second source layer includes a surface directly contacting the tunnel dielectric layer and the channel layer. The third source layer includes a top surface directly contacting the blocking layer. A width of the surface of the second source layer is greater than a width of the top surface of the third source layer.

### BRIEF DESCRIPTION OF DRAWINGS

FIG. 1A illustrates a simplified block diagram showing an electronic system including a semiconductor device according to some embodiments.

FIG. 1B illustrates a simplified perspective view showing an electronic system including a semiconductor device according to some embodiments.

FIGS. 1C and 1D illustrate simplified cross-sectional views showing a semiconductor package according to some embodiments.

FIG. 2A illustrates a plan view showing a semiconductor device according to some embodiments.

FIG. 2B illustrates a cross-sectional view taken along line A-A′ of FIG. 2A according to some embodiments.

FIG. 2C illustrates an enlarged view showing section E of FIG. 2B according to some embodiments.

FIG. 3 illustrates an enlarged view showing a semiconductor device according to some embodiments.

FIG. 4 illustrates an enlarged view showing a semiconductor device according to some embodiments.

FIGS. 5, 6A, 6B, 7A, 7B, 8A, 8B, 9A, 9B, 10A, 10B, 11A, 11B, 12A, and 12B illustrate diagrams showing a method of fabricating a semiconductor device according to some embodiments.

### DETAILED DESCRIPTION OF EMBODIMENTS

It will be hereinafter discussed a semiconductor device and a method of fabricating the same according to some embodiments of the present inventive concept in conjunction with the accompanying drawings.

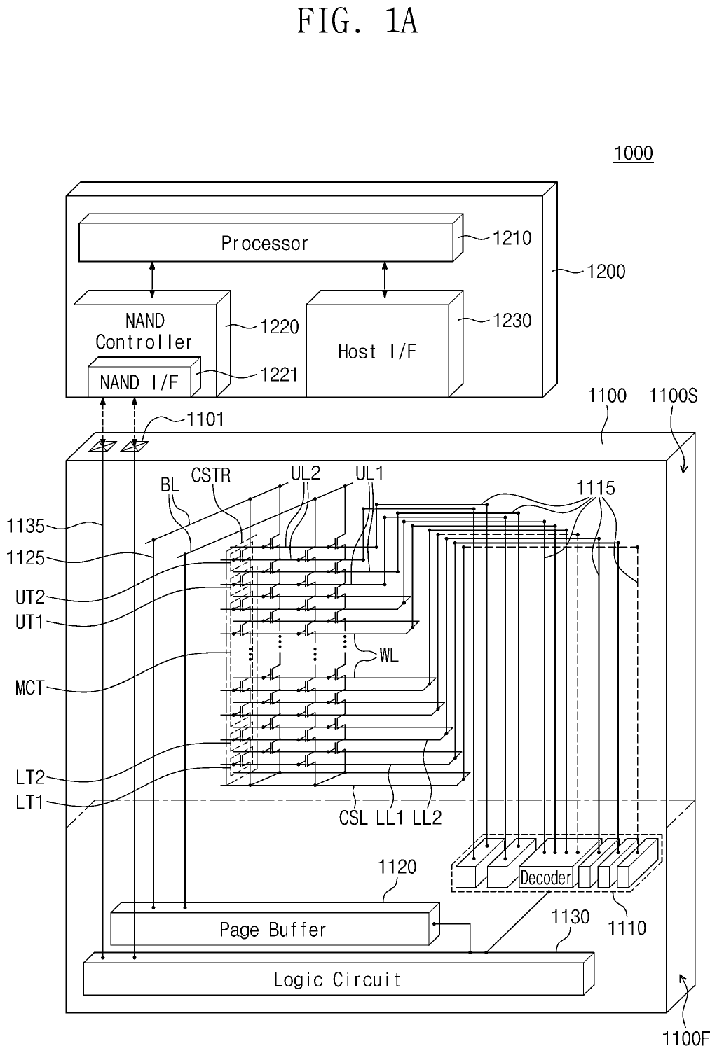

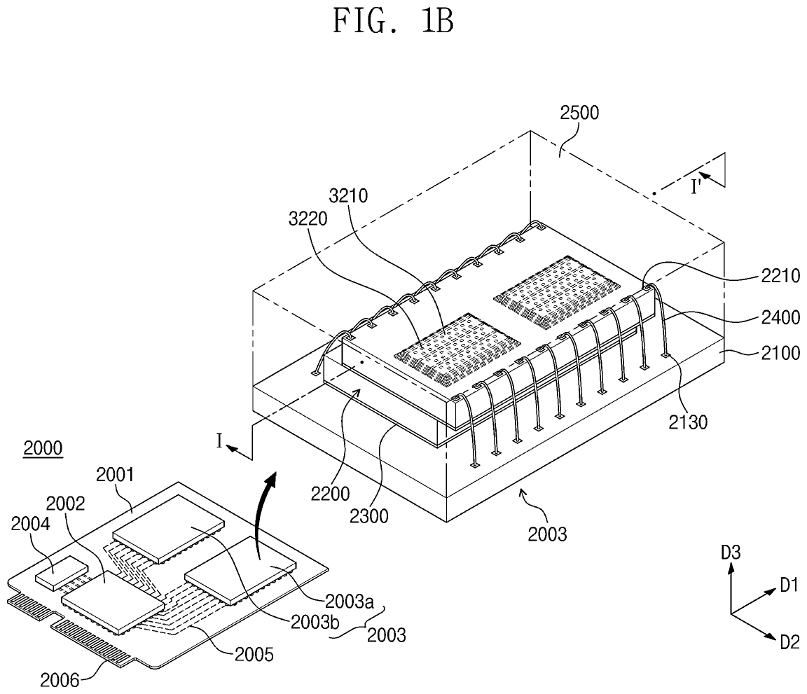

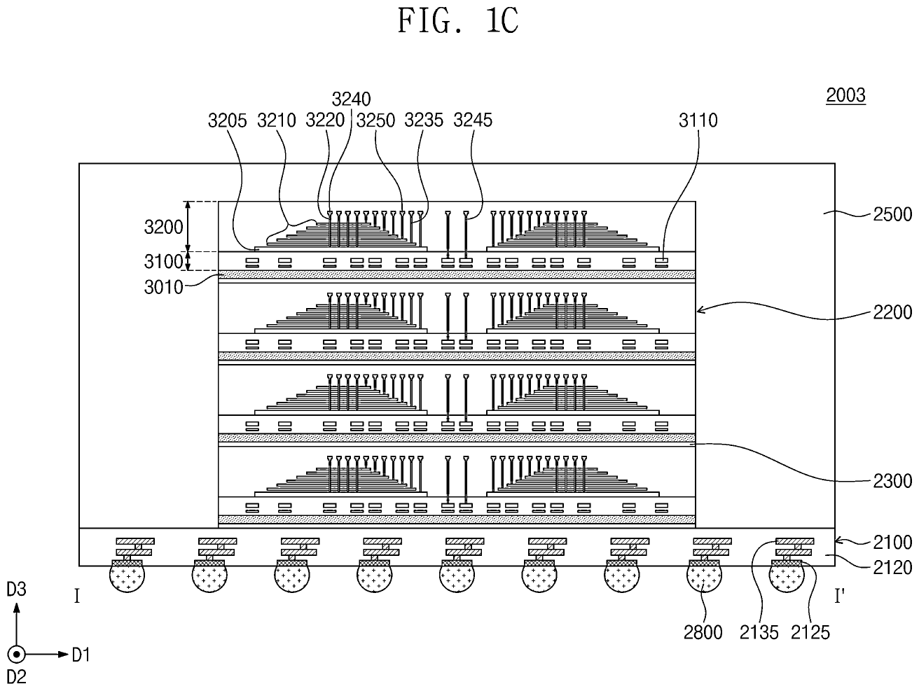

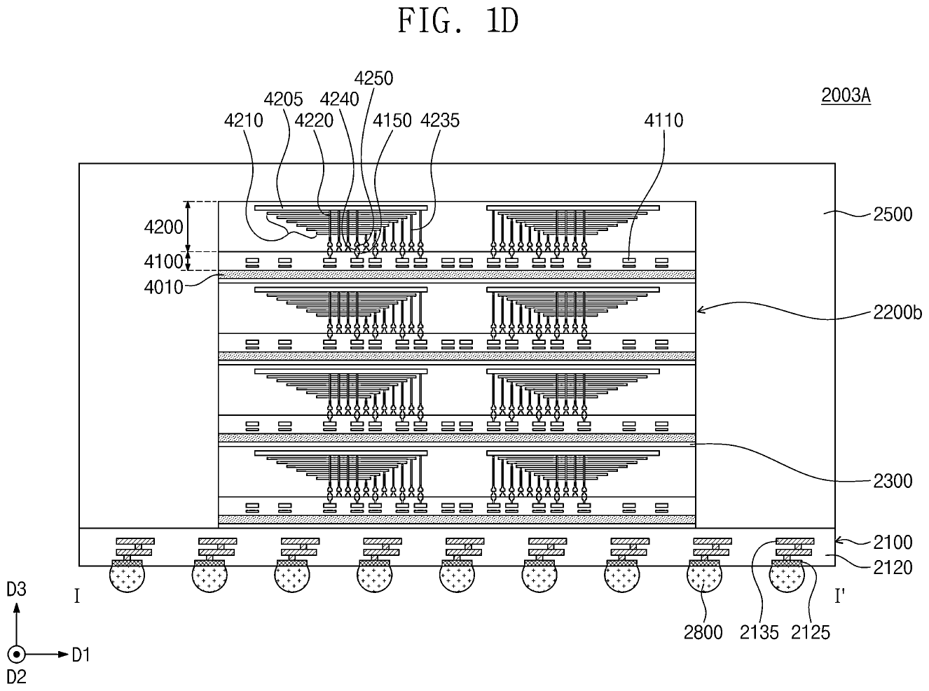

FIG. 1A illustrates a simplified block diagram showing an electronic system including a semiconductor device according to some embodiments of the present inventive concepts.

Referring to FIG. 1A, an electronic system 1000 according to some embodiments may include a semiconductor device 1100 and a controller 1200 electrically connected to the semiconductor device 1100. The electronic system 1000 may be a storage device that includes a single or a plurality of semiconductor devices 1100, or may be an electronic device that includes the storage device. For example, in an embodiment the electronic system 1000 may be a solid state drive (SSD) device, a universal serial bus (USB), a computing system, a medical apparatus, or a communication apparatus, each of which includes a single or a plurality of semiconductor devices 1100.

In an embodiment, the semiconductor device 1100 may be a nonvolatile memory device, such as a NAND Flash memory device. The semiconductor device 1100 may include a first structure 1100F and a second structure 1100S on the first structure 1100F (e.g., directly thereon in the vertical direction). However, embodiments of the present disclosure are not necessarily limited thereto. For example, in some embodiments the first structure 1100F may be disposed on a lateral side of the second structure 1100S. In an embodiment, the first structure 1100F may be a peripheral circuit structure that includes a decoder circuit 1110, a page buffer 1120, and a logic circuit 1130. The second structure 1100S may be a memory cell structure that includes a bit line BL, a common source line CSL, word lines WL, first and second gate upper lines UL1 and UL2, first and second gate lower lines LL1 and LL2, and memory cell strings CSTR between the bit line BL and the common source line CSL.

In the second structure 1100S, each of the memory cell strings CSTR may include lower transistors LT1 and LT2 adjacent to the common source line CSL, upper transistors UT1 and UT2 adjacent to the bit line BL, and memory cell transistors MCT disposed between the lower transistors LT1 and LT2 and the upper transistors UT1 and UT2. The number of the lower transistors LT1 and LT2 and of the upper transistors UT1 and UT2 may be variously changed in accordance with embodiments.

In some embodiments, the upper transistors UT1 and UT2 may include a string selection transistor, and the lower transistors LT1 and LT2 may include a ground selection transistor. The gate lower lines LL1 and LL2 may be gate electrodes of the lower transistors LT1 and LT2, respectively. The word lines WL may be gate electrodes of the memory cell transistors MCT, and the gate upper lines UL1 and UL2 may be gate electrodes of the upper transistors UT1 and UT2, respectively.

In an embodiment, the common source line CSL, the first and second gate lower lines LL1 and LL2, the word lines WL, and the first and second gate upper lines UL1 and UL2 may be electrically connected to the decoder circuit 1110 through first connection lines 1115 that extend from the first structure 1100F to the second structure 1100S. The bit lines BL may be electrically connected to the page buffer 1120 through second connection lines 1125 that extend from the first structure 1100F to the second structure 1100S.

In an embodiment, in the first structure 1100F, the decoder circuit 1110 and the page buffer 1120 may perform a control operation on at least one selection memory cell transistor among the plurality of memory cell transistors MCT. The logic circuit 1130 may control the decoder circuit 1110 and the page buffer 1120. The semiconductor device 1100 may communicate with the controller 1200 through an input/output pad 1101 electrically connected to the logic circuit 1130. The input/output pad 1101 may be electrically connected to the logic circuit 1130 through an input/output connection line 1135 that extends from the first structure 1100F to the second structure 1100S.

In an embodiment, the controller 1200 may include a processor 1210, a NAND controller 1220, and a host interface 1230. In some embodiments, the electronic system 1000 may include a plurality of semiconductor devices 1100, and in this embodiment, the controller 1200 may control each of the plurality of semiconductor devices 1100.

The processor 1210 may control an overall operation of the electronic system 1000 that includes the controller 1200. For example, in an embodiment the processor 1210 may operate based on predetermined firmware, and may control the NAND controller 1220 to access the semiconductor device 1100. The NAND controller 1220 may include a NAND interface 1221 that processes communication with the semiconductor device 1100. In an embodiment, the NAND interface 1221 may be used to transfer therethrough a control command to control the semiconductor device 1100, data intended to be written on the memory cell transistors MCT of the semiconductor device 1100, and/or data intended to be read from the memory cell transistors MCT of the semiconductor device 1100. The host interface 1230 may provide the electronic system 1000 with communication with an external host. When a control command is received through the host interface 1230 from an external host, the semiconductor device 1100 may be controlled by the processor 1210 in response to the control command.

FIG. 1B illustrates a simplified perspective view showing an electronic system including a semiconductor device according to some embodiments.

Referring to FIG. 1B, an electronic system 2000 according to some example embodiments may include a main board 2001, a controller 2002 mounted on the main board 2001, at least one semiconductor package 2003, and a dynamic random access memory (DRAM) 2004. In an embodiment, the semiconductor package 2003 and the DRAM 2004 may be connected to the controller 2002 through wiring patterns 2005 formed on the main board 2001.

In an embodiment, the main board 2001 may include a connector 2006 including a plurality of pins which will be connected to an external host. The number and arrangement of the plurality of pins on the connector 2006 may vary based on a communication interface between the electronic system 2000 and the external host. In some embodiments, the electronic system 2000 may communicate with the external host through one or more interfaces, for example, universal serial bus (USB), peripheral component interconnect express (PIC-Express), serial advanced technology attachment (SATA), and/or M-PHY for universal flash storage (UFS). However, embodiments of the present disclosure are not necessarily limited thereto. In some embodiments, the electronic system 2000 may operate with power supplied through the connector 2006 from an external host. In some embodiments, the electronic system 2000 may further include a power management integrated circuit (PMIC) by which the power supplied from the external host is distributed to the controller 2002 and the semiconductor package 2003.

The controller 2002 may write data to the semiconductor package 2003, may read data from the semiconductor package 2003, or may increase an operating speed of the electronic system 2000.

In an embodiment, the DRAM 2004 may be a buffer memory that reduces a difference in speed between the external host and the semiconductor package 2003 that serves as a data storage space. For example, in some embodiments the DRAM 2004 included in the electronic system 2000 may operate as a type of cache memory, and may provide a space for temporary data storage in a control operation of the semiconductor package 2003. In an embodiment in which the DRAM 2004 is included in the electronic system 2000, the controller 2002 may include not only a NAND controller for controlling the semiconductor package 2003, but also a DRAM controller for controlling the DRAM 2004.

In an embodiment as shown in FIG. 1B, the semiconductor package 2003 may include first and second semiconductor packages 2003a and 2003b that are spaced apart from each other. However, embodiments of the present disclosure are not necessarily limited thereto and the number of the semiconductor packages may vary. Each of the first and second semiconductor packages 2003a and 2003b may be a semiconductor package including a plurality of semiconductor chips 2200. In an embodiment, each of the first and second semiconductor package 2003a and 2003b may include a package substrate 2100, semiconductor chips 2200 on the package substrate 2100, adhesion layers 2300 on bottom surfaces of the semiconductor chips 2200, connection structures 2400 that electrically connect the semiconductor chips 2200 to the package substrate 2100, and a molding layer 2500 that lies on the package substrate 2100 and covers the semiconductor chips 2200 and the connection structures 2400.

In an embodiment, the package substrate 2100 may be an integrated circuit board including package upper pads 2130. Each of the semiconductor chips 2200 may include one or more input/output pads 2210. The input/output pad 2210 may correspond to the input/output pad 1101 of FIG. 1A. Each of the semiconductor chips 2200 may include gate stack structures 3210 and memory channel structures 3220. Each of the semiconductor chips 2200 may include a semiconductor device which will be discussed below.

In some embodiments, the connection structures 2400 may be bonding wires that electrically connect the input/output pads 2210 to the package upper pads 2130. Therefore, in each of the first and second semiconductor packages 2003a and 2003b, the semiconductor chips 2200 may be electrically connected to each other in a wire bonding manner, and may be electrically connected to the package upper pads 2130 of the package substrate 2100. In some embodiments, in each of the first and second semiconductor packages 2003a and 2003b, the semiconductor chips 2200 may be electrically connected to each other using through silicon vias (TSVs) instead of the connection structures 2400 or the bonding wires.

In some embodiments, the controller 2002 and the semiconductor chips 2200 may be included in one package. In some embodiments, the controller 2002 and the semiconductor chips 2200 may be mounted on a separate interposer substrate other than the main board 2001, and may be connected to each other through connection lines provided in the interposer substrate.

FIGS. 1C and 1D illustrate simplified cross-sectional views showing a semiconductor package according to some embodiments. FIGS. 1C and 1D each depicts a non-limiting embodiment of the semiconductor package 2003 shown in FIG. 1B, conceptually showing a section taken along line I-I′ of the semiconductor package 2003 shown in FIG. 1B.

Referring to FIG. 1C, a printed circuit board may be used as the package substrate 2100 of the semiconductor package 2003. In an embodiment, the package substrate 2100 may include a package substrate body 2120, upper pads (see 2130 of FIG. 1B) disposed on a top surface of the package substrate body 2120, lower pads 2125 disposed or exposed on a bottom surface of the package substrate body 2120, and internal lines 2135 that are disposed in the package substrate body 2120 and electrically connect the upper pads 2130 to the lower pads 2125. In an embodiment, the upper pads 2130 may be electrically connected to connection structures (see 2400 of FIG. 1B). The lower pads 2125 may be connected through conductive connectors 2800 to the wiring patterns 2005 on the main board 2001 of the electronic system 2000, as shown in FIG. 1B.

In an embodiment, each of the semiconductor chips 2200 may include a semiconductor substrate 3010, and may also include a first structure 3100 and a second structure 3200 that are sequentially stacked on the semiconductor substrate 3010 (e.g., in a vertical direction). In an embodiment, the first structure 3100 may include a peripheral circuit region including peripheral wiring lines 3110. The second structure 3200 may include a common source line 3205, a gate stack structure 3210 on the common source line 3205, memory channel structures 3220 that penetrate (e.g., in the vertical direction) the gate stack structure 3210, bit lines 3240 electrically connected to the memory channel structures 3220, and gate contact plugs 3235 electrically connected to corresponding word lines (see WL of FIG. 1A) of the gate stack structure 3210.

In an embodiment, each of the semiconductor chips 2200 may include through wiring lines 3245 that are electrically connected to the peripheral wiring lines 3110 of the first structure 3100 and extend into the second structure 3200. The through wiring line 3245 may be disposed outside the gate stack structure 3210. In some embodiments, the through wiring line 3245 may penetrate the gate stack structure 3210. Each of the semiconductor chips 2200 may further include an input/output pad (see 2210 of FIG. 1B).

Referring to FIG. 1D, in an embodiment in a semiconductor package 2003A, each of semiconductor chips 2200b may include a semiconductor substrate 4010, a first structure 4100 on the semiconductor substrate 4010, and a second structure 4200 disposed on, and wafer-bonded to, the first structure 4100.

In an embodiment, the first structure 4100 may include a peripheral circuit region including a peripheral wiring line 4110 and first bonding structures 4150. The second structure 4200 may include a common source line 4205, a gate stack structure 4210 between the common source line 4205 and the first structure 4100, memory channel structures 4220 that penetrate (e.g., in a vertical direction) the gate stack structure 4210, bit lines 4240 electrically connected to the memory channel structures 420, gate contact plugs 4235 electrically connected to corresponding word lines (see WL of FIG. 1A) of the gate stack structure 4210, and second bonding structures 4250. For example, the second bonding structures 4250 may be electrically connected to corresponding memory channel structures 4220 through the bit lines 4240 electrically connected to the memory channel structures 4220. The first bonding structures 4150 of the first structure 4100 may be bonded to the second bonding structures 4250 of the second structure 4200. In an embodiment, the first and second bonding structures 4150 and 4250 may have their bonding portions formed of, for example, copper (Cu). However, embodiments of the present disclosure are not necessarily limited thereto. Each of the semiconductor chips 2200b may further include an input/output pad (see 2210 of FIG. 1B).

In an embodiment, the semiconductor chips 2200 of FIG. 1C or the semiconductor chips 2200b of FIG. 1D may be electrically connected to each other through the connection structures (see 2400 of FIG. 1B) shaped like bonding wires. In some embodiments, semiconductor chips in one semiconductor package, such as the semiconductor chips 2200 of FIG. 1C or the semiconductor chips 2200b of FIG. 1D, may be electrically connected to each other through connection structures including through electrodes (TSVs).

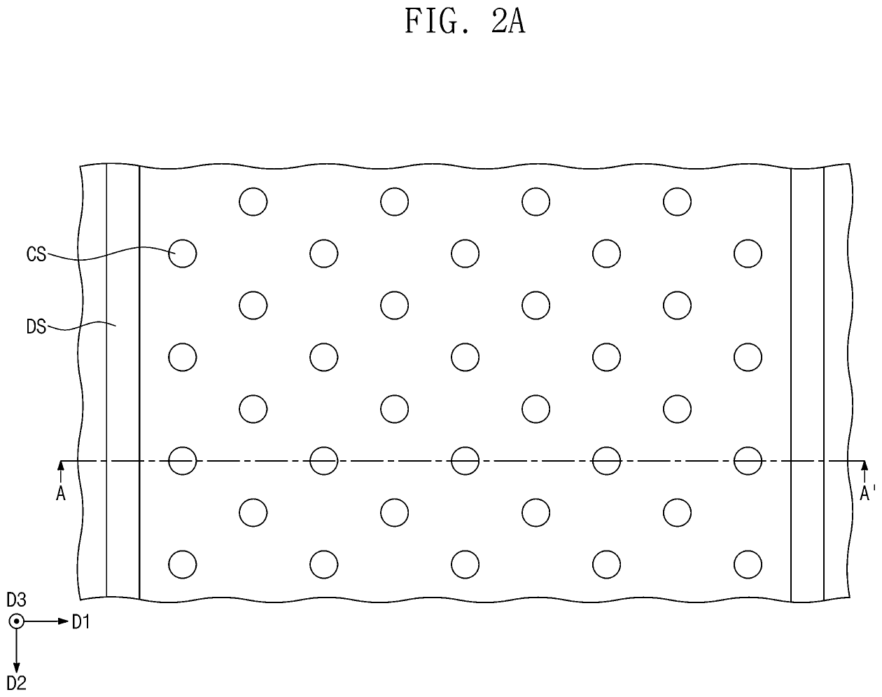

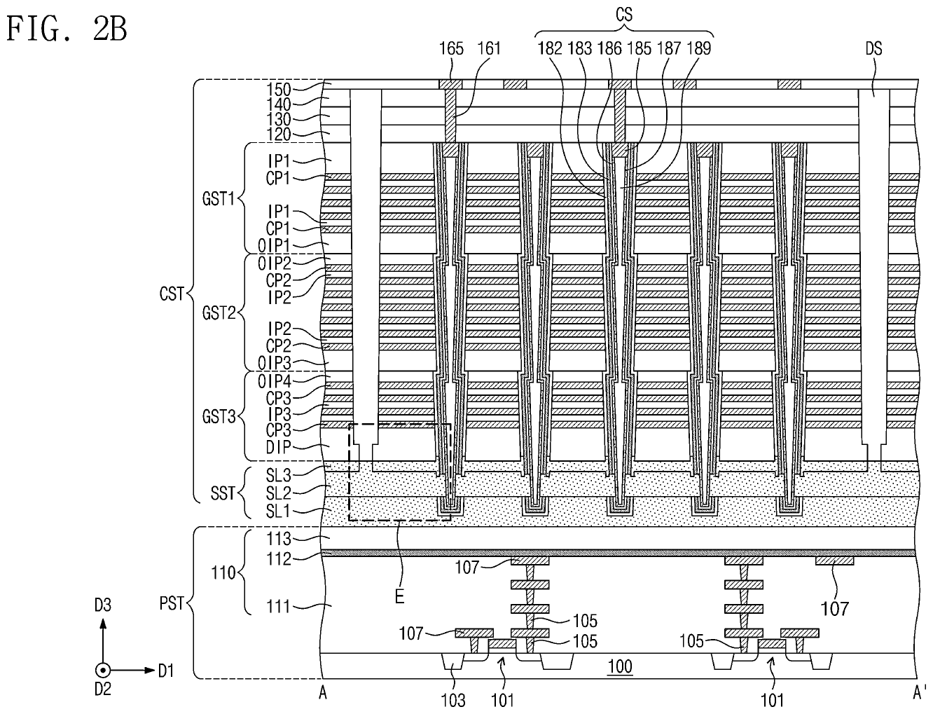

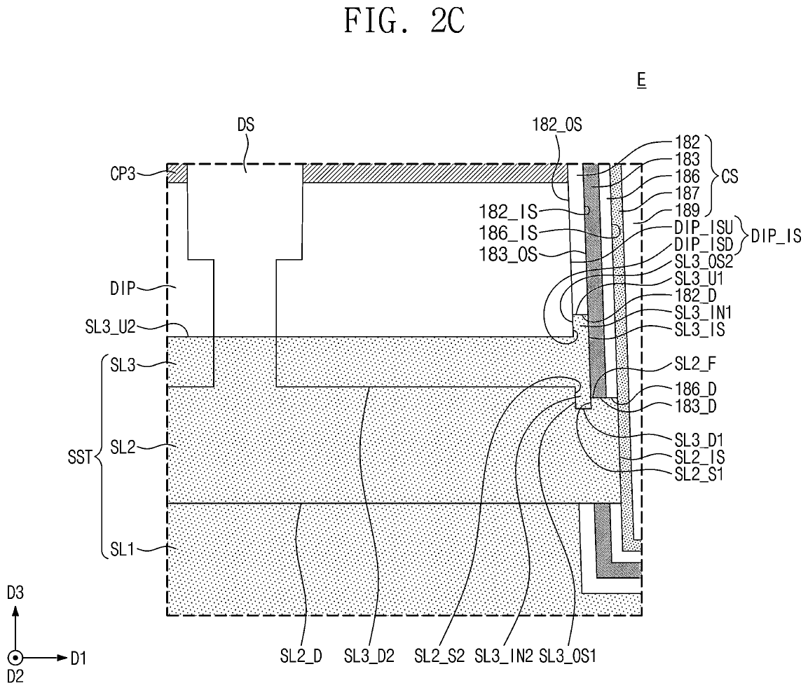

FIG. 2A illustrates a plan view showing a semiconductor device according to some embodiments. FIG. 2B illustrates a cross-sectional view taken along line A-A′ of FIG. 2A. FIG. 2C illustrates an enlarged view showing section E of FIG. 2B.

Referring to FIGS. 2A, 2B, and 2C, a semiconductor device may include a peripheral circuit structure PST and a memory cell structure CST on the peripheral circuit structure PST (e.g., directly thereon in the vertical direction).

The peripheral circuit structure PST may include a substrate 100. In an embodiment, the substrate 100 may have a plate shape that is elongated along a plane defined by a first direction D1 and a second direction D2. The first direction D1 and the second direction D2 may intersect each other. For example, the first direction D1 and the second direction D2 may be horizontal directions that are orthogonal to each other. However, embodiments of the present disclosure are not necessarily limited thereto and the first and second directions D1, D2 may cross each other at various different angles. A third direction D3 may be orthogonal to the first and second directions D1, D2 and may be a vertical direction that is a thickness direction of the substrate 100. In some embodiments, the substrate 100 may be a semiconductor substrate. For example, in an embodiment the substrate 100 may include silicon (Si), germanium (Ge), silicon-germanium (SiGe), gallium phosphide (GaP), or gallium arsenide (GaAs). In some embodiments, the substrate 100 may be a silicon-on-insulator (SOI) substrate or a germanium-on-insulator (GOI) substrate.

The peripheral circuit structure PST may include a peripheral circuit dielectric structure 110 on the substrate 100. In an embodiment, the peripheral circuit dielectric structure 110 may include a first peripheral circuit dielectric layer 111, a second peripheral circuit dielectric layer 112 on (e.g., directly thereon in the third direction D3) the first peripheral circuit dielectric layer 111, and a third peripheral circuit dielectric layer 113 on (e.g., directly thereon in the third direction D3) the second peripheral circuit dielectric layer 112. The first, second, and third peripheral circuit dielectric layers 111, 112, and 113 may include a dielectric material. For example, in an embodiment the first and third peripheral circuit dielectric layers 111 and 113 may include oxide, and the second peripheral circuit dielectric layer 112 may include nitride. In some embodiments, one or more of the first, second, and third peripheral circuit dielectric layers 111, 112, and 113 may be a multiple dielectric layer.

The peripheral circuit structure PST may further include a peripheral transistor 101. The peripheral transistor 101 may be disposed between the substrate 100 and the peripheral circuit dielectric structure 110. In some embodiments, the peripheral transistor 101 may include source/drain regions, a gate electrode, and a gate dielectric layer. The substrate 100 may have device isolation layers 103 therein. The peripheral transistor 101 may be disposed between the device isolation layers 103. The device isolation layer 103 may include a dielectric material.

In an embodiment, the memory cell structure CST may include a source structure SST, a first gate stack structure GST1, a second gate stack structure GST2, a third gate stack structure GST3, memory channel structures CS, separation structures DS, bit-line contacts 161, and bit lines 165.

In an embodiment, the source structure SST may include a first source layer SL1 on the peripheral circuit structure PST (e.g., directly thereon in the third direction D3), a second source layer SL2 on the first source layer SL1 (e.g., directly thereon in the third direction D3), and a third source layer SL3 on the second source layer SL2 (e.g., directly thereon in the third direction D3).

The first, second, and third source layers SL1, SL2, and SL3 may include a conductive material. For example, in an embodiment the first, second, and third source layers SL1, SL2, and SL3 may include polysilicon. The second source layer SL2 may be a common source line.

The third gate stack structure GST3 may be disposed on the source structure SST (e.g., directly thereon in the third direction D3). The second gate stack structure GST2 may be disposed on the third gate stack structure GST3 (e.g., directly thereon in the third direction D3). The first gate stack structure GST1 may be disposed on the second gate stack structure GST2 (e.g., directly thereon in the third direction D3). However, embodiments of the present disclosure are not necessarily limited to the number of the gate stack structures GST1, GST2, and GST3 shown in FIG. 2B. In some embodiments, the number of the gate stack structures GST1, GST2, and GST3 may be less than or equal to 2 or greater than or equal to 4.

In an embodiment, the first gate stack structure GST1 may include first dielectric patterns IP1 and first conductive patterns CP1 that are alternately stacked along the third direction D3. The first dielectric patterns IP1 may include a first connection dielectric pattern OIP1 that is a lowermost one of the first dielectric patterns IP1.

The second gate stack structure GST2 may include second dielectric patterns IP2 and second conductive patterns CP2 that are alternately stacked along the third direction D3. The second dielectric patterns IP2 may include a second connection dielectric pattern OIP2 that is an uppermost one of the second dielectric patterns IP2. In an embodiment, the second connection dielectric pattern OIP2 may be in direct contact with the first connection dielectric pattern OIP1. The second dielectric patterns IP2 may include a third connection dielectric pattern OIP3 that is a lowermost one of the second dielectric patterns IP2.

The third gate stack structure GST3 may include third dielectric patterns IP3 and third conductive patterns CP3 that are alternately stacked along the third direction D3. The third dielectric patterns IP3 may include a fourth connection dielectric pattern OIP4 that is an uppermost one of the third dielectric patterns IP3. In an embodiment, the fourth connection dielectric pattern OIP4 may be in direct contact with the third connection dielectric pattern OIP3. The third dielectric patterns IP3 may include a lower dielectric pattern DIP which is a lowermost one of the third dielectric patterns IP3. In an embodiment, the lower dielectric pattern DIP may be in direct contact with the third source layer SL3 of the source structure SST.

The first, second, and third dielectric patterns IP1, IP2, and IP3 may include a dielectric material. For example, in an embodiment the first, second, and third dielectric patterns IP1, IP2, and IP3 may include oxide. The first, second, and third conductive patterns CP1, CP2, and CP3 may include a conductive material. For example, in an embodiment the first, second, and third conductive patterns CP1, CP2, and CP3 may include tungsten.

In an embodiment, the memory channel structures CS may extend in the third direction D3 to penetrate (e.g., in the third direction D3) the first gate stack structure GST1, the second gate stack structure GST2, the third gate stack structure GST3, the second source layer SL2, and the third source layer SL3.

In an embodiment, each of the memory channel structures CS may include a dielectric capping layer 189, a channel layer 187 that surrounds the dielectric capping layer 189, a tunnel dielectric layer 186 that surrounds the channel layer 187, a data storage layer 183 that surrounds the tunnel dielectric layer 186, and a blocking layer 182 that surrounds the data storage layer 183.

The dielectric capping layer 189 and the tunnel dielectric layer 186 may include a dielectric material. For example, in an embodiment the dielectric capping layer 189 and the tunnel dielectric layer 186 may include oxide.

The channel layer 187 may include a conductive material. For example, in an embodiment the channel layer 187 may include polysilicon. The channel layer 187 may be in direct contact with the second source layer SL2. For example, an inner sidewall SL2_IS of the second source layer SL2 may directly contact the channel layer 187. The channel layer 187 may be electrically connected to the second source layer SL2. The channel layer 187 may be spaced apart from the third source layer SL3.

The data storage layer 183 may store data. In some embodiments, the data storage layer 183 may include a ferroelectric material. For example, in an embodiment the ferroelectric material may include at least one compound selected from hafnium oxide, hafnium silicon oxide, hafnium zirconium oxide, hafnium tantalum oxide, lanthanum oxide, zirconium oxide, zirconium silicon oxide, tantalum oxide, titanium oxide, barium strontium titanium oxide, barium titanium oxide, strontium titanium oxide, lithium oxide, aluminum oxide, lead scandium tantalum oxide, and lead zinc niobate. A polarization switching of the ferroelectric material may allow the data storage layer 183 of the memory channel structure CS to store and/or change data. In some embodiments, the data storage layer 183 may include a material capable of trapping charges. For example, in an embodiment the data storage layer 183 may include nitride.

The blocking layer 182 may include a dielectric material. For example, the blocking layer 182 may include at least one compound selected from oxide and nitride. The blocking layer 182 may be spaced apart from the second source layer SL2. For example, an upper surface of the second source layer SL2 may be spaced apart from the blocking layer 182 by the third source layer SL3. The blocking layer 182 may be in direct contact with the third source layer SL3.

Each of the memory channel structures CS may further include a bit-line pad 185 disposed on the channel layer 187. The bit-line pad 185 may include a conductive material. For example, in an embodiment the bit-line pad 185 may include polysilicon or metal.

A first cover dielectric layer 120 may be disposed on (e.g., disposed directly thereon in the third direction D3) the first gate stack structure GST1 and the memory channel structures CS. The first cover dielectric layer 120 may include a dielectric material. A second cover dielectric layer 130 may be disposed on (e.g., disposed directly thereon in the third direction D3) the first cover dielectric layer 120. The second cover dielectric layer 130 may include a dielectric material.

A third cover dielectric layer 140 may be disposed on (e.g., disposed directly thereon in the third direction D3) the second cover dielectric layer 130. A fourth cover dielectric layer 150 may be disposed on (e.g., disposed directly thereon in the third direction D3) the third cover dielectric layer 140 and the separation structures DS. The third and fourth cover dielectric layers 140 and 150 may include a dielectric material.

The separation structures DS may penetrate (e.g., in the third direction DR3) the first, second, and third gate stack structures GST1, GST2, and GST3. The separation structures DS may extend in the second direction D2. The separation structures DS may include a dielectric material. In some embodiments, the separation structures DS may further include a conductive material.

A bit-line contact 161 may be connected to (e.g., directly connected thereto) the memory channel structure CS. The bit-line contact 161 may penetrate (e.g., in the third direction D3) the first, second, and third cover dielectric layers 120, 130, and 140. The bit line 165 may be connected to the bit-line contact 161. The bit line 165 may be disposed in the fourth cover dielectric layer 150. The bit line 165 may extend in the first direction D1. The bit-line contact 161 and the bit line 165 may include a conductive material.

The second source layer SL2 may include a bottom surface SL2_D in direct contact with the first source layer SL1. A boundary between the first source layer SL1 and the second source layer SL2 may be defined by the bottom surface SL2_D of the second source layer SL2. The second source layer SL2 may include a surface SL2_F in direct contact with a bottom surface 183_D of the data storage layer 183 and a bottom surface 186_D of the tunnel dielectric layer 186. In an embodiment, the surface SL2_F may be relatively flat (e.g., extend along the first direction D1).

The second source layer SL2 may include an inner sidewall SL2_IS that connects the bottom surface SL2_D of the second source layer SL2 to the surface SL2_F of the second source layer SL2. The inner sidewall SL2_IS of the second source layer SL2 may be in direct contact with the channel layer 187. The second source layer SL2 may include a first sidewall SL2_S1 and a second sidewall SL2_S2. The first sidewall SL2_S1 and the second sidewall SL2_S2 may be in direct contact with a second intervening portion SL3_IN2 of the third source layer SL3 which will be discussed below. The surface SL2_F of the second source layer SL2 may connect to each other the first sidewall SL2_S1 and the inner sidewall SL2_IS of the second source layer SL2.

The third source layer SL3 may include a first bottom surface SL3_D1, a second bottom surface SL3_D2, a first outer sidewall SL3_OS1, and an inner sidewall SL3_IS. The first bottom surface SL3_D1, the second bottom surface SL3_D2, the first outer sidewall SL3_OS1, and the inner sidewall SL3_IS of the third source layer SL3 may be in direct contact with the second source layer SL2. The first outer sidewall SL3_OS1 of the third source layer SL3 may connect to each other the first bottom surface SL3_D1 and the second bottom surface SL3_D2 of the third source layer SL3. A boundary between the second source layer SL2 and the third source layer SL3 may be defined by the first bottom surface SL3_D1, the second bottom surface SL3_D2, the first outer sidewall SL3_OS1, and the inner sidewall SL3_IS of the third source layer SL3.

The inner sidewall SL3_IS of the third source layer SL3 may be in direct contact with the data storage layer 183 of the memory channel structure CS. The surface SL2_F of the second source layer SL2 may be disposed between the inner sidewall SL3_IS of the third source layer SL3 and the channel layer 187 of the memory channel structure CS (e.g., in the first direction D1).

The third source layer SL3 may include a first top surface SL3_U1 in direct contact with a bottom surface 182_D of the blocking layer 182. The third source layer SL3 may include a second outer sidewall SL3_OS2 and a second top surface SL3_U2 in direct contact with the lower dielectric pattern DIP. The inner sidewall SL3_IS of the third source layer SL3 may connect to each other the first bottom surface SL3_D1 and the first top surface SL3_U1 of the third source layer SL3. The second outer sidewall SL3_OS2 of the third source layer SL3 may connect to each other the first top surface SL3_U1 and the second top surface SL3_U2 of the third source layer SL3.

The first outer sidewall SL3_OS1, the second outer sidewall SL3_OS2, and the inner sidewall SL3_IS of the third source layer SL3 may be parallel to each other. However, embodiments of the present disclosure are not necessarily limited thereto. For example, in some embodiments, the first outer sidewall SL3_OS1, the second outer sidewall SL3_OS2, and the inner sidewall SL3_IS of the third source layer SL3 may not be parallel to each other.

The lower dielectric pattern DIP may include an inner sidewall DIP_IS in direct contact with the third source layer SL3 and the blocking layer 182 of the channel structure CS. For example, the inner sidewall DIP_IS of the lower dielectric pattern DIP may include a lower portion DIP_ISD in direct contact with the second outer sidewall SL3_OS2 of the third source layer SL3 and an upper portion DIP_ISU in direct contact with an outer sidewall 182_OS of the blocking layer 182.

The surface SL2_F of the second source layer SL2 may be positioned at a higher level (e.g., distance from the substrate 100 in the third direction D3) than that of the first bottom surface SL3_D1 of the third source layer SL3. The level of the surface SL2_F of the second source layer SL2 may be lower than that of the first top surface SL3_U1 of the third source layer SL3. The level of the surface SL2_F of the second source layer SL2 may be lower than that of the second top surface SL3_U2 of the third source layer SL3. The level of the surface SL2_F of the second source layer SL2 may be lower than that of a bottom surface of the lower dielectric pattern DIP. In an embodiment, the surface SL2_F of the second source layer SL2 may have a width (e.g., length in the first direction D1) that is greater than that of the first top surface SL3_U1 of the third source layer SL3.

In an embodiment, the level of the first bottom surface SL3_D1 of the third source layer SL3 may be lower than that of the second bottom surface SL3_D2 of the third source layer SL3. The level of the first bottom surface SL3_D1 of the third source layer SL3 may be lower than that of the bottom surface 183_D of the data storage layer 183 and that of the bottom surface 186_D of the tunnel dielectric layer 186.

The level of the first top surface SL3_U1 of the third source layer SL3 may be higher than that of the second top surface SL3_U2 of the third source layer SL3. The level of the first top surface SL3_U1 of the third source layer SL3 may be higher than that of the bottom surface of the lower dielectric pattern DIP. The bottom surface 182_D of the blocking layer 182 may be positioned at a higher level than that of the bottom surface 186_D of the tunnel dielectric layer 186 and that of the bottom surface 183_D of the data storage layer 183.

The third source layer SL3 may include a first intervening portion SL3_IN1 and a second intervening portion SL3_IN2. The first intervening portion SL3_IN1 of the third source layer SL3 may be interposed between the lower portion DIP_ISD of the inner sidewall DIP_IS of the lower dielectric pattern DIP and the data storage layer 183 of the memory channel structure CS (e.g., in the first direction D1). The first intervening portion SL3_IN1 of the third source layer SL3 may have a top surface in direct contact with the blocking layer 182. The top surface of the first intervening portion SL3_IN1 of the third source layer SL3 may be positioned at a higher level than that of the surface SL2_F of the second source layer SL2. The second intervening portion SL3_IN2 of the third source layer SL3 may be interposed between the first sidewall SL2_S1 and the second sidewall SL2_S2 of the second source layer SL2 (e.g., in the first direction D1). The second intervening portion SL3_IN2 of the third source layer SL3 may have a bottom surface at a lower level than that of the surface SL2_F of the second source layer SL2.

The first sidewall SL2_S1 of the second source layer SL2 may be coplanar with an outer sidewall 183_OS of the data storage layer 183. The inner sidewall SL2_IS of the second source layer SL2 may be coplanar with an inner sidewall 186_S of the tunnel dielectric layer 186.

The second outer sidewall SL3_OS2 of the third source layer SL3 may be coplanar with the outer sidewall 182_OS of the blocking layer 182. The inner sidewall SL3_IS of the third source layer SL3 may be coplanar with an inner sidewall 182_IS of the blocking layer 182.

The bottom surface 183_D of the data storage layer 183 may be coplanar with the bottom surface 186_D of the tunnel dielectric layer 186.

The semiconductor device according to some embodiments may include the third source layer SL3 in direct contact with the bottom surface 182_D of the blocking layer 182. As the third source layer SL3 is in direct contact with the blocking layer 182, the blocking layer 182 may be closed by the third source layer SL3. Therefore, when the data storage layer 183 and the tunnel dielectric layer 186 are partially removed to form the second source layer SL2, the blocking layer 182 may be prevented from being etched. As the blocking layer 182 is prevented from being etched, there may be a reduction in a level difference between the bottom surfaces 182_D of the blocking layers 182 included in the memory channel structures CS, which may result in increased electrical properties.

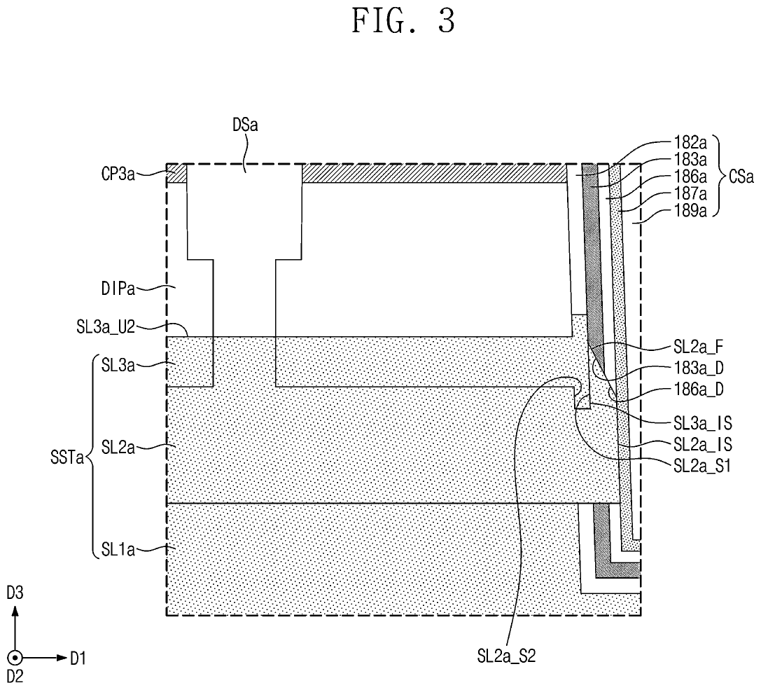

FIG. 3 illustrates an enlarged view showing a semiconductor device according to some embodiments.

Referring to FIG. 3, a source structure SSTa of a semiconductor device may include a first source layer SL1a, a second source layer SL2a, and a third source layer SL3a. In an embodiment, a memory channel structure CSa may include a dielectric capping layer 189a, a channel layer 187a, a tunnel dielectric layer 186a, a data storage layer 183a, and a blocking layer 182a.

The second source layer SL2a may include an inner sidewall SL2a_IS, first and second sidewalls SL2a_S1 and SL2a_S2, and a surface SL2a_F. The third source layer SL3a may include an inner sidewall SL3a_IS. The surface SL2a_F of the second source layer SL2a may be disposed between the inner sidewall SL3a_IS of the third source layer SL3a and the channel layer 187a of the memory channel structure CSa (e.g., in the first direction D1). The third source layer SL3a may be interposed between the first sidewall SL2a_S1 and the second sidewall SL2a_S2 of the second source layer SL2a (e.g., in the first direction D1).

The surface SL2a_F of the second source layer SL2a may be inclined. The surface SL2a_F of the second source layer SL2a may intersect the inner sidewall SL3a_IS of the third source layer SL3a. For example, an angle of the surface SL2a_F and the inner sidewall SL2a_IS of the second source layer SL2a may be in a range of about 90 degrees to about 180 degrees. An angle between the surface SL2a_F and the first sidewall SL2a_S1 of the second source layer SL2a may be in a range of about 0 degree to about 90 degrees.

A bottom surface 183a_D of the data storage layer 183a and a bottom surface 186a_D of the tunnel dielectric layer 186a may be in direct contact with the surface SL2a_F of the second source layer SL2a. The bottom surface 183a_D of the data storage layer 183a may be coplanar with the bottom surface 186a_D of the tunnel dielectric layer 186a. The bottom surface 183a_D of the data storage layer 183a may be inclined, and the bottom surface 186a_D of the tunnel dielectric layer 186a may also be inclined. For example, the bottom surface 183a_D of the data storage layer 183a and the bottom surface 186a_D of the tunnel dielectric layer 186a may be inclined at a same angle as each other. The bottom surface 183a_D of the data storage layer 183a may intersect the inner sidewall SL3a_IS of the third source layer SL3a. For example, an angle between the bottom surface 183a_D of the data storage layer 183a and the first sidewall SL2a_S1 of the second source layer SL2a may be in a range of about 0 degrees to about 90 degrees. An angle between the bottom surface 186a_D of the tunnel dielectric layer 186a and the inner sidewall SL2a_IS of the second source layer SL2a may be in a range of about 90 degrees to about 180 degrees.

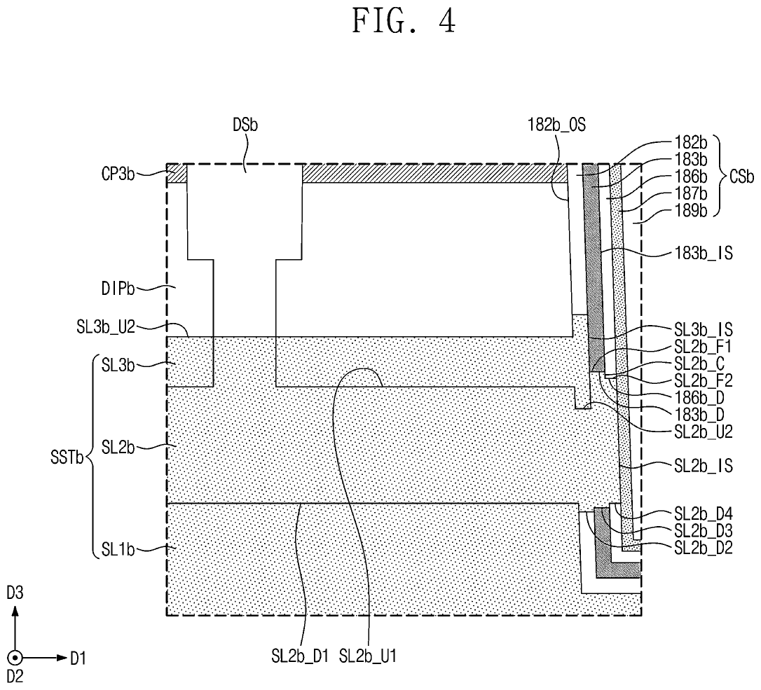

Referring to FIG. 4, a source structure SSTb of a semiconductor device may include a first source layer SL1b, a second source layer SL2b, and a third source layer SL3b. In an embodiment, a memory channel structure CSb may include a dielectric capping layer 189b, a channel layer 187b, a tunnel dielectric layer 186b, a data storage layer 183b, and a blocking layer 182b.

The second source layer SL2b may include bottom surfaces SL2b_D1, SL2b_D2, SL2b_D3, and SL2b_D4, first and second top surfaces SL2b_U1 and SL2b_U2, first and second surfaces SL2b_F1 and SL2b_F2, a connection surface SL2b_C, and an inner sidewall SL2b_IS.

The bottom surfaces SL2b_D1, SL2b_D2, SL2b_D3, and SL2b_D4 of the second source layer SL2b may include first, second, third, and fourth bottom surfaces SL2b_D1, SL2b_D2, SL2b_D3, and SL2b_D4. The first bottom surface SL2b_D1 of the second source layer SL2b may be in direct contact with the first source layer SL1b. The first top surface SL2b_U1 and the second top surface SL2b_U2 of the second source layer SL2b may be in direct contact with the third source layer SL3b. The second bottom surface SL2b_D2 of the second source layer SL2b may be in direct contact with the blocking layer 182b. The third bottom surface SL2b_D3 and the first surface SL2b_F1 of the second source layer SL2b may be in direct contact with the data storage layer 183b. The first surface SL2b_F1 of the second source layer SL2b may be in direct contact with a bottom surface 183b_D of the data storage layer 183b. The fourth bottom surface SL2b_D4 and the second surface SL2b_F2 of the second source layer SL2b may be in direct contact with the tunnel dielectric layer 186b. The second surface SL2b_F2 of the second source layer SL2b may be in direct contact with a bottom surface 186b_D of the tunnel dielectric layer 186b. The connection surface SL2b_C of the second source layer SL2b may connect the first surface SL2b_F1 and the second surface SL2b_F2 to each other. The connection surface SL2b_C of the second source layer SL2b may be coplanar with an inner sidewall 183b_IS of the data storage layer 183b.

In an embodiment, the third bottom surface SL2b_D3 of the second source layer SL2b may be positioned at a higher level (e.g., in the third direction D3) than that of the second bottom surface SL2b_D2 of the second source layer SL2b. The fourth bottom surface SL2b_D4 of the second source layer SL2b may be positioned at a higher level (e.g., in the third direction D3) than that of the third bottom surface SL2b_D3 of the second source layer SL2b. The first bottom surface SL2b_D1 of the second source layer SL2b may be positioned at a higher level (e.g., in the third direction D3) than that of the fourth bottom surface SL2b_D4 of the second source layer SL2.

The level of the first top surface SL2b_U1 of the second source layer SL2b may be higher than that of the second top surface SL2b_U2 of the second source layer SL2b (e.g., in the third direction D3). The first surface SL2b_F1 of the second source layer SL2b may be positioned at a higher level than that of the second surface SL2b_F2 of the second source layer SL2b (e.g., in the third direction D3). The level of the second surface SL2b_F2 of the second source layer SL2b may be higher than that of the second top surface SL2b_U2 of the second source layer SL2b (e.g., in the third direction D3).

The inner sidewall SL2b_IS of the second source layer SL2b may connect to each other the fourth bottom surface SL2b_D4 and the second surface SL2b_F2 of the second source layer SL2b. The first and second surfaces SL2b_F1 and SL2b_F2 of the second source layer SL2b may be disposed between an inner sidewall SL3b_IS of the third source layer SL3 and the channel layer 187b of the memory channel structure CSb (e.g., in the first direction D1). The first surface SL2b_F1 of the second source layer SL2b may be disposed between an inner sidewall SL3b_IS of the third source layer SL3b and the tunnel dielectric layer 186b of the memory channel structure CSb.

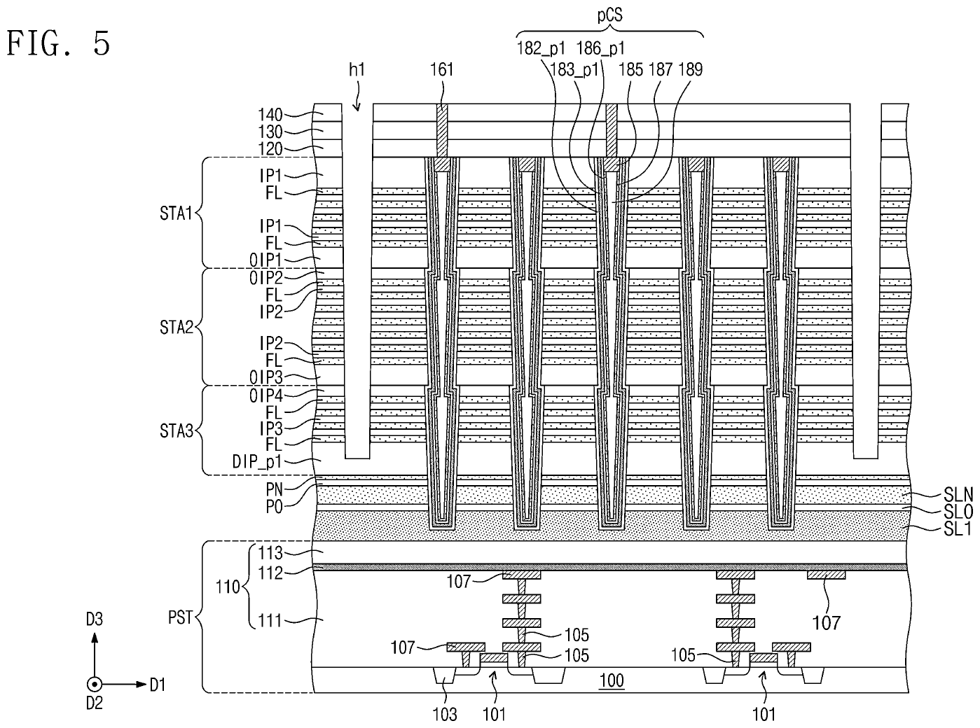

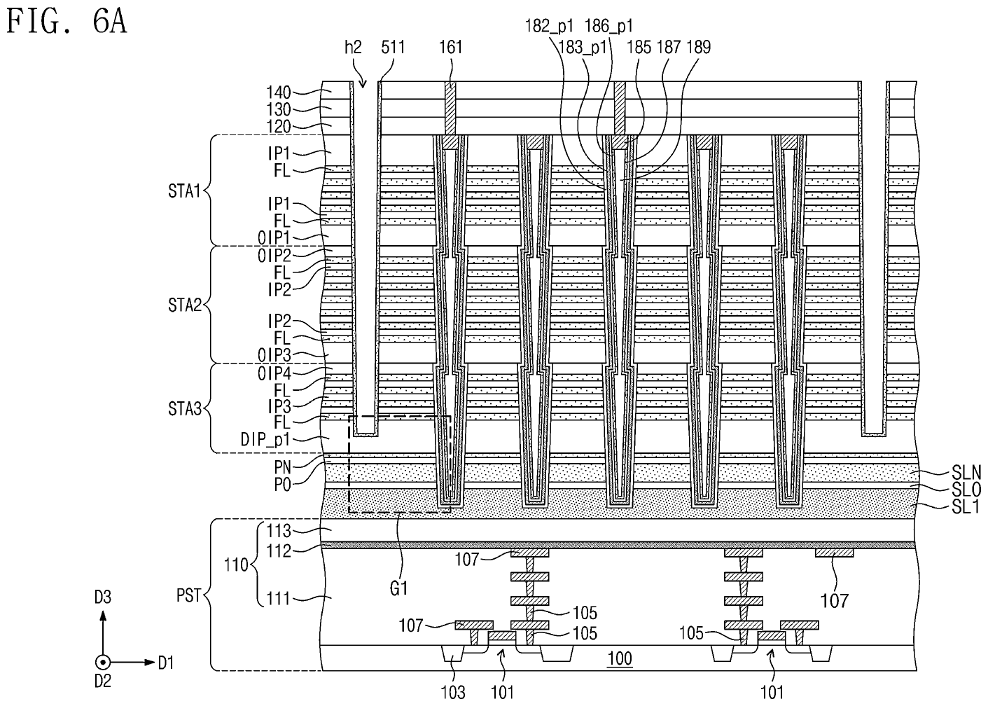

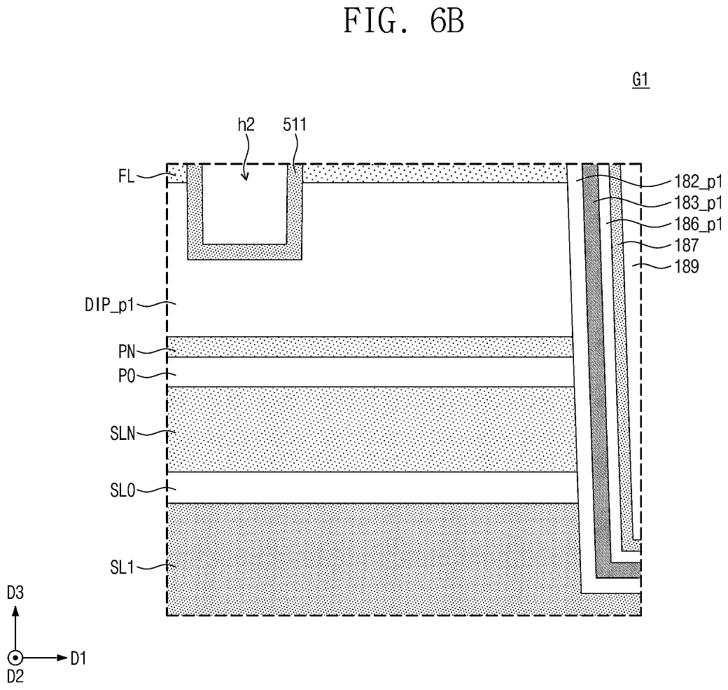

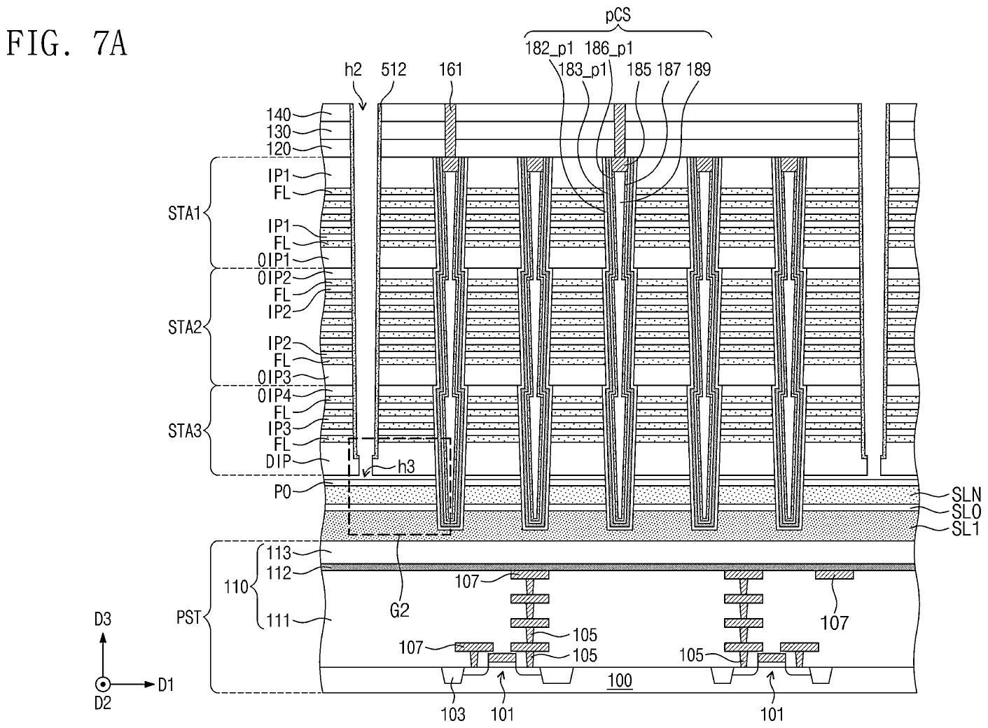

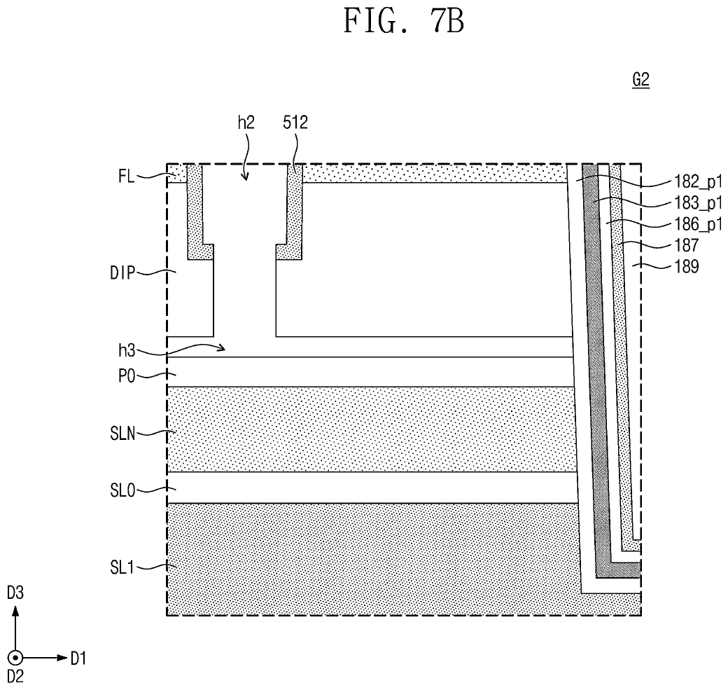

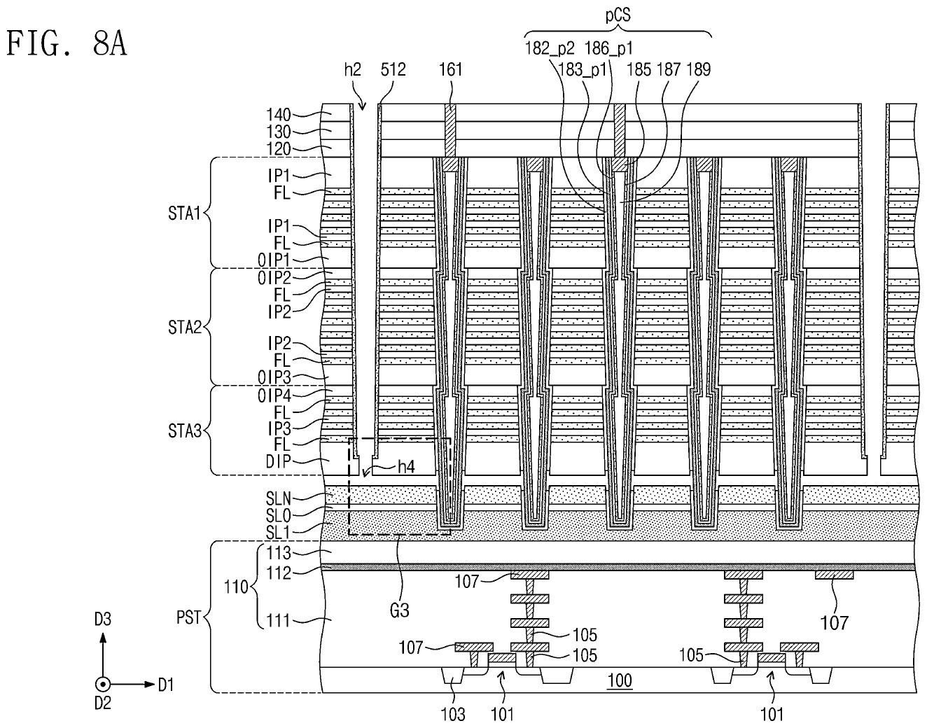

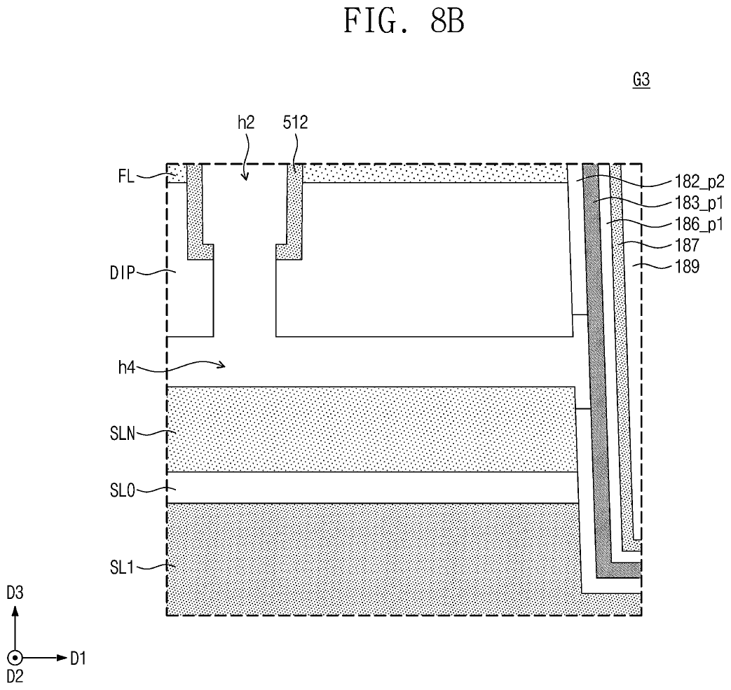

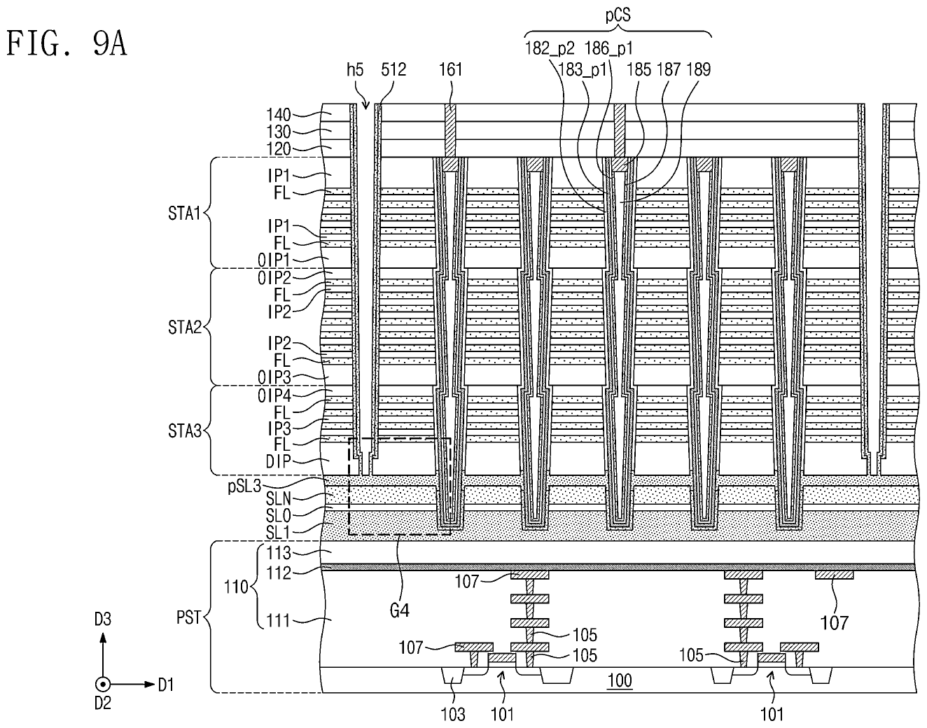

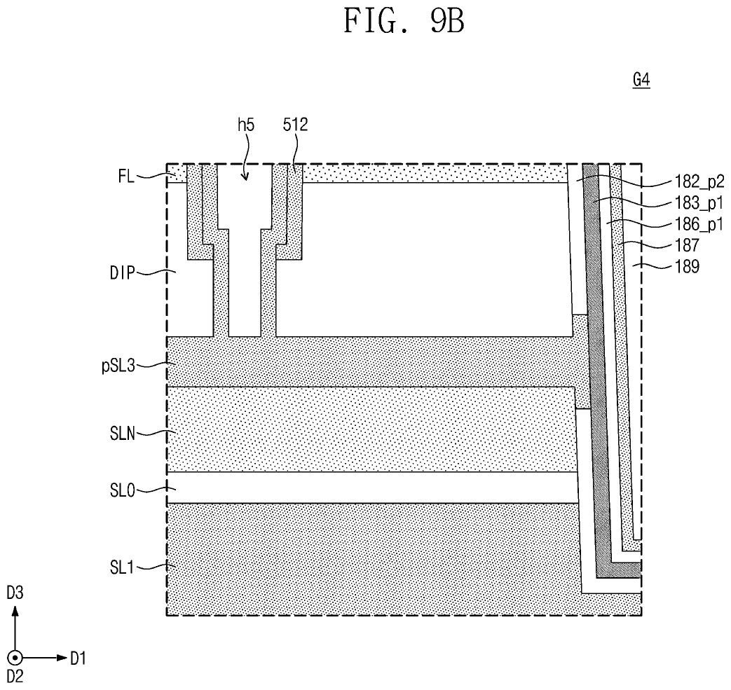

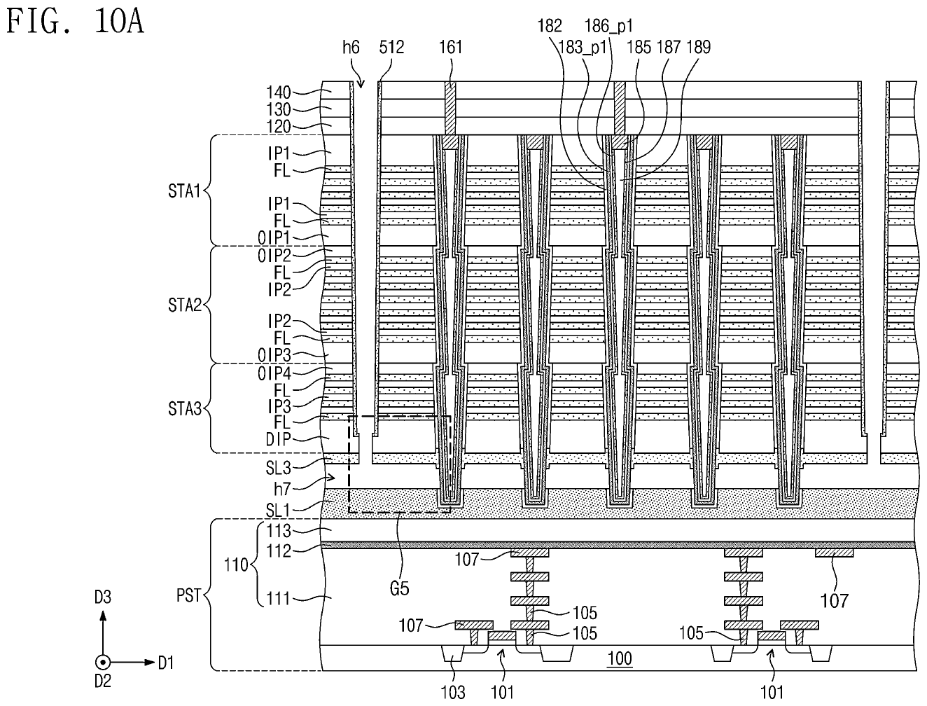

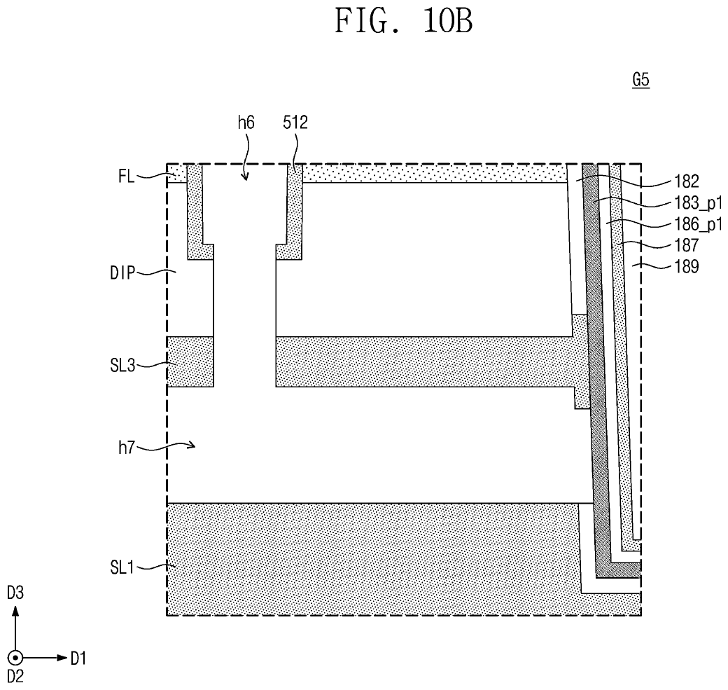

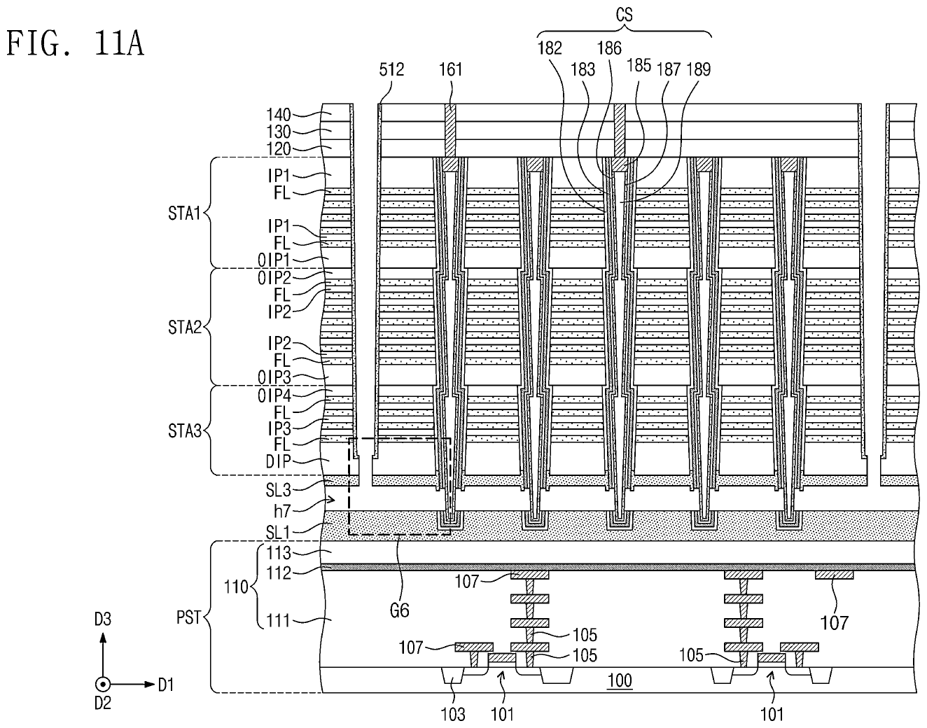

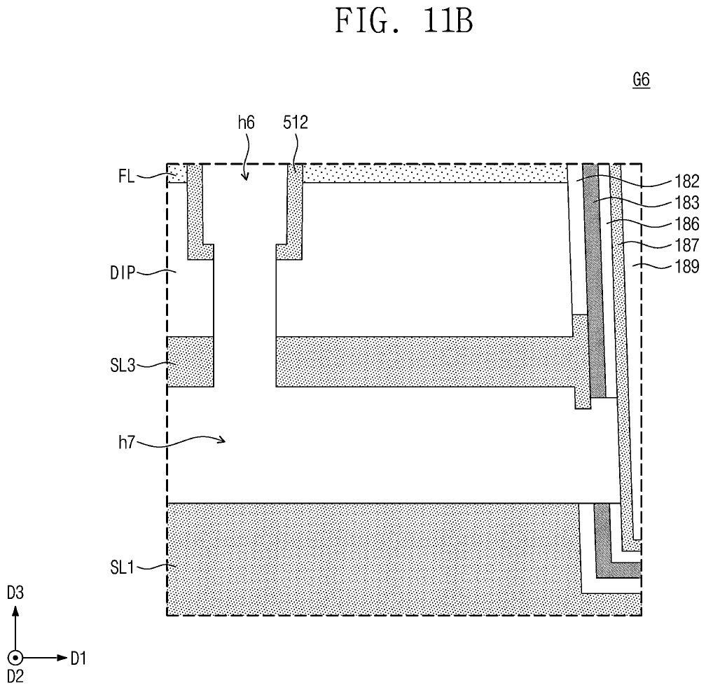

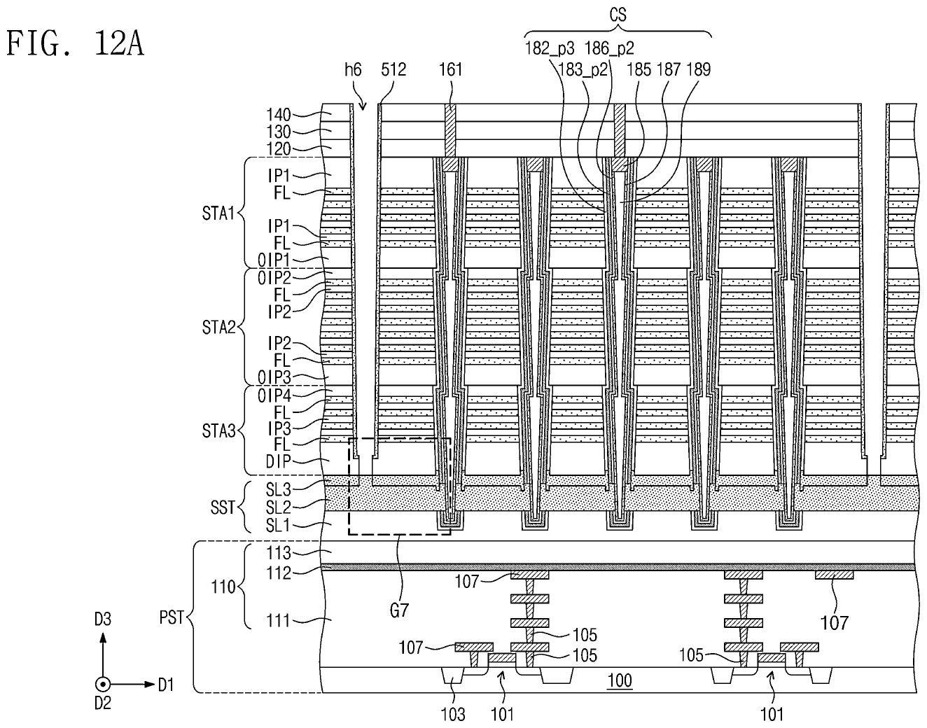

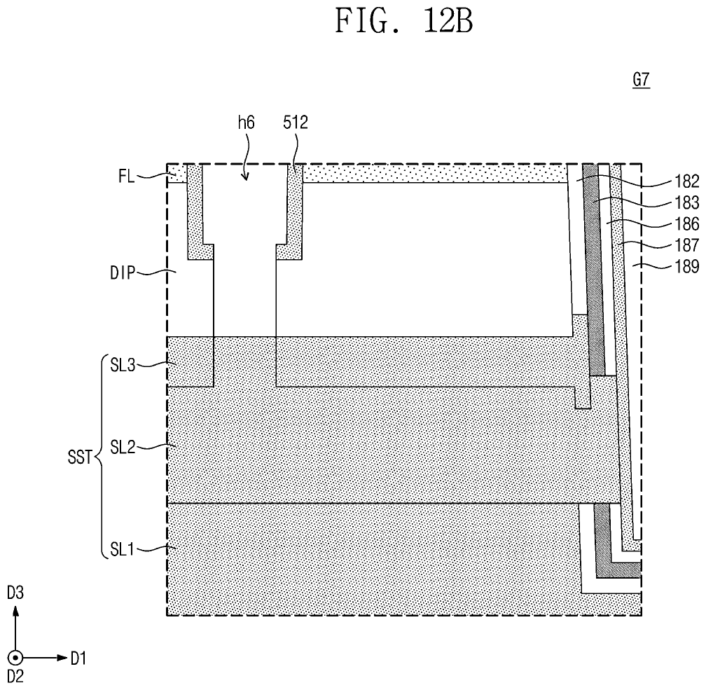

FIGS. 5, 6A, 6B, 7A, 7B, 8A, 8B, 9A, 9B, 10A, 10B, 11A, 11B, 12A, and 12B illustrate diagrams showing a method of fabricating a semiconductor device according to some embodiments. FIGS. 5, 6A, 7A, 8A, 9A, 10A, 11A, and 12A may correspond to FIG. 2B. FIG. 6B illustrates an enlarged view showing section G1 of FIG. 6A. FIG. 7B illustrates an enlarged view showing section G2 of FIG. 7A. FIG. 8B illustrates an enlarged view showing section G3 of FIG. 8A. FIG. 9B illustrates an enlarged view showing section G4 of FIG. 9A. FIG. 10B illustrates an enlarged view showing section G5 of FIG. 10A. FIG. 11B illustrates an enlarged view showing section G6 of FIG. 11A. FIG. 12B illustrates an enlarged view showing section G7 of FIG. 12A.

Referring to FIG. 5A, in an embodiment a peripheral circuit structure PST, a first source layer SL1, a first sacrificial source layer SLO, a second sacrificial source layer SLN, a third sacrificial source layer PO, a fourth sacrificial source layer PN, a first stack structure STA1, a second stack structure STA2, a third stack structure STA3, a first cover dielectric layer 120, a second cover dielectric layer 130, a third cover dielectric layer 140, preliminary memory channel structures pCS, and bit-line contacts 161 may be formed.

The first source layer SL1 may be formed on (e.g., formed directly thereon in the third direction D3) the peripheral circuit structure PST, the first sacrificial source layer SLO may be formed on (e.g., formed directly thereon in the third direction D3) the first source layer SL1, the second sacrificial source layer SLN may be formed on the first sacrificial source layer SLO, the third sacrificial source layer PO may be formed on (e.g., formed directly thereon in the third direction D3) the second sacrificial source layer SLN, and the fourth sacrificial source layer PN may be formed on (e.g., formed directly thereon in the third direction D3) the third sacrificial source layer PO. The first, second, third, and fourth sacrificial source layers SLO, SLN, PO, and PN may include a dielectric material. For example, in an embodiment the first and third sacrificial source layers SLO and PO may include oxide. The second and fourth sacrificial source layers SLN and PN may include nitride.

The first, second, and third stack structures STA1, STA2, and STA3 may be formed on the fourth sacrificial source layer PN. For example, in an embodiment the third stack structure STA3 may directly contact the fourth sacrificial source layer PN. The first stack structure STA1 may include first dielectric patterns IP1 and sacrificial layers FL that are alternately stacked (e.g., in the third direction D3). The second stack structure STA2 may include second dielectric patterns IP2 and sacrificial layers FL that are alternately stacked (e.g., in the third direction D3). The third stack structure STA3 may include third dielectric patterns IP3 and sacrificial layers FL that are alternately stacked (e.g., in the third direction D3). The dielectric patterns IP1, IP2, and IP3 may include a dielectric material different from that of the sacrificial layers FL. For example, in an embodiment the dielectric patterns IP1, IP2, and IP3 may include oxide, and the sacrificial layers FL may include nitride.

The third stack structure STA3 may be formed on (e.g., formed directly thereon in the third direction D3) the fourth sacrificial source layer PN. A preliminary lower dielectric pattern DIP_p1 may be defined to indicate a third dielectric pattern IP3 positioned at the lowest part of the third stack structure STA3.

The second stack structure STA2 may be formed on (e.g., formed directly thereon in the third direction D3) the third stack structure STA3. The first stack structure STA1 may be formed on (e.g., formed directly thereon in the third direction D3) the second stack structure STA2.

The preliminary memory channel structure pCS may be formed to penetrate (e.g., in the third direction D3) the second, third, and fourth sacrificial source layers SLN, PO, and PN and the first, second, and third stack structures STA1, STA2, and STA3. In an embodiment, the preliminary memory channel structure pCS may include a dielectric capping layer 189, a channel layer 187 that surrounds the dielectric capping layer 189, a preliminary tunnel dielectric layer 186_p1 that surrounds the channel layer 187, a preliminary data storage layer 183_p1 that surrounds the preliminary tunnel dielectric layer 186_p1, and a first preliminary blocking layer 182_p1 that surrounds the preliminary data storage layer 183_p1.

The first cover dielectric layer 120 may be formed on (e.g., formed directly thereon in the third direction D3) the first stack structure STA1 and the preliminary memory channel structures pCS, the second cover dielectric layer 130 may be formed on (e.g., formed directly thereon in the third direction D3) the first cover dielectric layer 120, and the third cover dielectric layer 140 may be formed on (e.g., formed directly thereon in the third direction D3) the second cover dielectric layer 130. A first opening h1 may be defined by the first, second, and third stack structures STA1, STA2, and STA3 and the first, second, and third cover dielectric layers 120, 130, and 140. The first opening h1 may expose the dielectric patterns IP1, IP2, and IP3 and the sacrificial layers FL of the first, second, and third stack structures STA1, STA2, and STA3.

Referring to FIGS. 6A and 6B, a first barrier layer 511 may be formed on (e.g., formed directly thereon) the first opening h1. The first barrier layer 511 may cover the dielectric patterns IP and the sacrificial layers FL of the first, second, and third stack structures STA1, STA2, and STA3, which conductive patterns IP1, IP2, and IP3 and the sacrificial layers FL are exposed by the first opening h1. The first barrier layer 511 may be formed on the first opening h1, thereby forming a second hole h2. The second opening h2 may be defined by surfaces (e.g., inner surfaces) of the first barrier layer 511. The first barrier layer 511 may include a conductive material. For example, in an embodiment the first barrier layer 511 may include polysilicon.

Referring to FIGS. 7A and 7B, in an embodiment the second opening h2 may be used to remove a portion of the first barrier layer 511, a portion of the preliminary lower dielectric pattern DIP_p1, and the fourth sacrificial source layer PN. A portion of the first barrier layer 511 may be removed to form a second barrier layer 512. The first barrier layer 511 having a portion that is removed may be defined as the second barrier layer 512. A portion of the preliminary lower dielectric pattern DIP_p1 may be removed to form a lower dielectric pattern DIP. The preliminary lower dielectric pattern DIP_p1 having a portion that is removed may be defined as the lower dielectric pattern DIP. A portion of the first barrier layer 511, a portion of the preliminary lower dielectric pattern DIP_p1, and the fourth sacrificial source layer PN may be removed to form a third opening h3. The third opening h3 may include empty spaces formed by removal of a portion of the first barrier layer 511, a portion of the preliminary lower dielectric pattern DIP_p1, and the fourth sacrificial source layer PN. The third opening h3 may expose the third sacrificial source layer PO and the first preliminary blocking layer 182_p1 of the preliminary memory channel structure pCS. In some embodiments, a wet etching process may be employed to remove a portion of the first barrier layer 511, a portion of the preliminary lower dielectric pattern DIP_p1, and the fourth sacrificial source layer PN. However, embodiments of the present disclosure are not necessarily limited thereto.

Referring to FIGS. 8A and 8B, in an embodiment the second opening h2 and the third opening h3 may be used to remove the third sacrificial source layer PO and a portion of the first preliminary blocking layer 182_p1. A portion of the first preliminary blocking layer 182_p1 may be removed to form a second preliminary blocking layer 182_p2. The first preliminary blocking layer 182_p1 having a portion that is removed may be defined as the second preliminary blocking layer 182_p2. In an embodiment, the third sacrificial source layer PO and a portion of the first preliminary blocking layer 182_p1 may be removed in one process. The third sacrificial source layer PO and a portion of the first preliminary blocking layer 182_p1 may be removed to form a fourth opening h4. The fourth opening h4 may include empty spaces included in the third opening h3, and may also include empty spaces formed by removal of the third sacrificial source layer PO and a portion of the first preliminary blocking layer 182_p1. The fourth opening h4 may expose the second sacrificial source layer SLN and the preliminary data storage layer 183_p1 of the preliminary memory channel structure pCS. In some embodiments, a wet etching process may be employed to remove the third sacrificial source layer PO and a portion of the first preliminary blocking layer 182_p1. However, embodiments of the present disclosure are not necessarily limited thereto.

Referring to FIGS. 9A and 9B, in an embodiment the second opening h2 and the fourth opening h4 may be used to form a third preliminary source layer pSL3. The third preliminary source layer pSL3 may cover the second barrier layer 512, the exposed second sacrificial source layer SLN, and the exposed preliminary data storage layer 183_p1 of the preliminary memory channel structure pCS. The third preliminary source layer pSL3 may fill the fourth opening h4. The third preliminary source layer pSL3 may be formed on the second opening h2 to form a fifth opening h5. The fifth opening h5 may be defined by surfaces of the third preliminary source layer pSL3. The third preliminary source layer pSL3 may include a conductive material. For example, in an embodiment the third preliminary source layer pSL3 may include polysilicon.

Referring to FIGS. 10A and 10B, in an embodiment the fifth opening h5 may be used to remove a portion of the third preliminary source layer pSL3. A portion of the third preliminary source layer pSL3 may be removed to form a sixth opening h6 and a third source layer SL3. The sixth opening h6 may include empty spaces included in the fifth opening h5, and may also include empty spaces formed by removal of a portion of the third preliminary source layer pSL3. The third preliminary source layer pSL3 having a portion that is removed may be defined as the third source layer SL3. The sixth opening h6 may expose the second barrier layer 512 and the lower dielectric pattern DIP.

The sixth opening h6 may be used to remove the first and second sacrificial source layers SLO and SLN and a portion of the first preliminary blocking layer 182_p1 of the preliminary memory channel structure pCS. The second sacrificial source layer SLN may be removed to expose the first sacrificial source layer SLO and the first preliminary blocking layer 182_p1 of the preliminary memory channel structure pCS. After the removal of the second sacrificial source layer SLN, a removal action may be performed to remove the first sacrificial source layer SLO and a portion of the first preliminary blocking layer 182_p1 of the preliminary memory channel structure pCS. A portion of the first preliminary blocking layer 182_p1 of the preliminary memory channel structure pCS may be removed to form a blocking layer 182. The first preliminary blocking layer 182_p1 having a portion that is removed may be defined as the blocking layer 182. The first sacrificial source layer SLO and a portion of the first preliminary blocking layer 182_p1 of the preliminary memory channel structure pCS may be removed to form a seventh opening h7. The seventh opening h7 may include empty spaces formed by removal of the first sacrificial source layer SLO and a portion of the first preliminary blocking layer 182_p1. The seventh opening h7 may be used to expose the first source layer SL1 and the preliminary data storage layer 183_p1. In an embodiment, the first sacrificial source layer SLO and a portion of the first preliminary blocking layer 182_p1 of the preliminary memory channel structure pCS may be removed in one process.

In some embodiments, a wet etching process may be employed to remove a portion of the third preliminary source layer pSL3, the first and second sacrificial source layers SLO and SLN and a portion of the first preliminary blocking layer 182_p1 of the preliminary memory channel structure pCS. However, embodiments of the present disclosure are not necessarily limited thereto.

Referring to FIGS. 11A and 11B, in an embodiment the sixth and seventh openings h6 and h7 may be used to remove a portion of the preliminary data storage layer 183_p1 and a portion of the preliminary tunnel dielectric layer 186_p1. A portion of the preliminary data storage layer 183_p1 may be removed to form a data storage layer 183. For example, the preliminary data storage layer 183_p1 having a portion that is removed may be defined as the data storage layer 183. After the partial removal of the preliminary data storage layer 183_p1, a portion of the preliminary tunnel dielectric layer 186_p1 may be removed to form a tunnel dielectric layer 186. The preliminary tunnel dielectric layer 186_p1 having a portion that is removed may be defined as the tunnel dielectric layer 186. The data storage layer 183 and the tunnel dielectric layer 186 may form a memory channel structure CS. A portion of the preliminary data storage layer 183_p1 and a portion of the preliminary tunnel dielectric layer 186_p1 may be removed to expose the channel layer 187. In some embodiments, a wet etching process may be employed to remove a portion of the preliminary data storage layer 183_p1 and a portion of the preliminary tunnel dielectric layer 186_p1. However, embodiments of the present disclosure are not necessarily limited thereto.

Referring to FIGS. 12A and 12B, in an embodiment the sixth opening h6 may be used to form a second source layer SL2. The second source layer SL2 may fill the seventh opening h7. As the second source layer SL2 is formed, a source structure SST may be obtained. The sixth opening h6 may expose the second source layer SL2.

Referring to FIGS. 2B and 2C, the sixth opening h6 may be used to remove the second barrier layer 512. For example, in an embodiment the second barrier layer 512 may be removed to form a separation opening. The separation opening may be used to remove the sacrificial layers FL of the first, second, and third stack structures STA1, STA2, and STA3. The exposed sacrificial layers FL may be removed. Empty spaces formed by removal of the sacrificial layers FL may be filled with a conductive material to form conductive patterns CP1, CP2, and CP3. The formation of the conductive patterns CP1, CP2, and CP3 may define first, second, and third gate stack structures GST1, GST2, and GST3. After the formation of the conductive patterns CP1, CP2, and CP3, a separation structure DS may be formed on (e.g., formed directly thereon) the separation opening. The separation structure DS may fill (e.g., completely fill) the separation opening. After the formation of the separation structures DS, a fourth cover dielectric layer 150 and bit lines 165 may be formed on the separation structures DS, the third cover dielectric layer 140, and the bit-line contacts 161.

According to a semiconductor device and an electronic system including the same in accordance with some embodiments of the present disclosure, since a blocking layer is closed by a third source layer, there may be a reduction in level difference between bottom surfaces of the blocking layers included in memory channel structures, which may result in increased electrical properties.

Although the present disclosure has been described in connection with the some non-limiting embodiments illustrated in the accompanying drawings, it will be understood by one of ordinary skill in the art that variations in form and detail may be made therein without departing from the spirit and essential feature of the present disclosure. The described embodiments should thus be considered illustrative and not restrictive. Moreover, embodiments discussed above may be combined with each other.

What is claimed is:

1. A semiconductor device, comprising:
a source structure that includes a first source layer, a second source layer on the first source layer, and a third source layer on the second source layer;
a gate stack structure on the source structure, the gate stack structure including dielectric patterns and conductive patterns that are alternately stacked; and
a memory channel structure penetrating the gate stack structure,
wherein the memory channel structure includes:
a channel layer;
a data storage layer surrounding the channel layer; and
a blocking layer surrounding the data storage layer,
wherein the second source layer includes an inner sidewall directly contacting the channel layer, and
wherein the third source layer includes an inner sidewall directly contacting the data storage layer.

2. The semiconductor device of claim 1, wherein the second source layer includes a surface directly contacting the data storage layer.

3. The semiconductor device of claim 2, wherein:
the third source layer includes a top surface directly contacting the blocking layer,
wherein a level of the top surface of the third source layer is higher than a level of the surface of the second source layer.

4. The semiconductor device of claim 2, wherein the surface of the second source layer is positioned between the channel layer and the inner sidewall of the third source layer.

5. The semiconductor device of claim 2, wherein the surface of the third source layer is inclined.

6. The semiconductor device of claim 2, wherein:
the memory channel structure includes a tunnel dielectric layer disposed between the channel layer and the data storage layer,
wherein the data storage layer includes a ferroelectric material.

7. The semiconductor device of claim 6, wherein:
each of the tunnel dielectric layer and the data storage layer includes a bottom surface directly contacting the surface of the second source layer;
the blocking layer includes a bottom surface directly contacting the third source layer; and
the bottom surface of each of the tunnel dielectric layer and the data storage layer is positioned at a level lower than a level of the bottom surface of the blocking layer.

8. The semiconductor device of claim 1, wherein:
a lowermost dielectric pattern of the dielectric patterns is a lower dielectric pattern;
the third source layer includes a top surface directly contacting the blocking layer; and
a level of the top surface of the third source layer is higher than a level of a bottom surface of the lower dielectric pattern.

9. The semiconductor device of claim 8, wherein:
the third source layer includes an outer sidewall directly contacting an inner sidewall of the lower dielectric pattern,
wherein the outer sidewall of the third source layer is parallel to an inner sidewall of the third source layer.

10. The semiconductor device of claim 9, wherein the outer sidewall of the third source layer is coplanar with an outer sidewall of the blocking layer.

11. The semiconductor device of claim 8, wherein:
the lower dielectric pattern includes an inner sidewall including an upper portion directly contacting the blocking layer and a lower portion directly contacting the third source layer; and
the third source layer includes an intervening portion between the data storage layer and the lower portion of the inner sidewall of the lower dielectric pattern.

12. The semiconductor device of claim 11, wherein:
the second source layer includes a surface directly contacting the data storage layer; and
a top surface of the intervening portion of the third source layer is positioned at a level higher than a level of the surface of the second source layer.

13. A semiconductor device, comprising:
a source structure that includes a first source layer, a second source layer on the first source layer, and a third source layer on the second source layer;
a gate stack structure on the source structure, the gate stack structure including dielectric patterns and conductive patterns that are alternately stacked; and
a memory channel structure penetrating the gate stack structure,
wherein the memory channel structure includes:
a channel layer;
a tunnel dielectric layer surrounding the channel layer;
a data storage layer surrounding the tunnel dielectric layer; and
a blocking layer surrounding the data storage layer,
wherein the blocking layer is spaced apart from an upper surface of the second source layer,
wherein the second source layer includes a surface directly contacting the tunnel dielectric layer and the data storage layer, and
wherein the third source layer includes a first top surface directly contacting the blocking layer.

14. The semiconductor device of claim 13, wherein:
the third source layer includes a second top surface directly contacting the dielectric patterns,
wherein the second top surface of the third source layer is positioned at a level lower than a level of the first top surface of the third source layer.

15. The semiconductor device of claim 14, wherein the level of the second top surface of the third source layer is higher than a level of the surface of the second source layer.

16. The semiconductor device of claim 13, wherein the surface of the second source layer includes:
a first surface directly contacting the data storage layer; and
a second surface directly contacting the tunnel dielectric layer.

17. The semiconductor device of claim 16, wherein a level of the first surface of the second source layer is higher than a level of the second surface of the second source layer.

18. The semiconductor device of claim 16, wherein the second source layer includes a connection surface connecting the first surface and the second surface to each other.

19. An electronic system, comprising:
a main board;
a semiconductor device on the main board; and
a controller on the main board, the controller is electrically connected to the semiconductor device,
wherein the semiconductor device includes:
a source structure including a first source layer, a second source layer on the first source layer, and a third source layer on the second source layer;
a gate stack structure on the source structure, the gate stack structure including dielectric patterns and conductive patterns that are alternately stacked; and
a memory channel structure penetrating the gate stack structure,
wherein a lowermost dielectric pattern of the dielectric patterns is a lower dielectric pattern, wherein the lower dielectric pattern directly contacts the third source layer,
wherein the memory channel structure includes:
a dielectric capping layer;
a channel layer surrounding the dielectric capping layer;
a tunnel dielectric layer surrounding the channel layer;
a data storage layer surrounding the tunnel dielectric layer; and
a blocking layer surrounding the data storage layer,
wherein the second source layer includes a surface directly contacting the tunnel dielectric layer and the channel layer,
wherein the third source layer includes a top surface directly contacting the blocking layer, and
wherein a width of the surface of the second source layer is greater than a width of the top surface of the third source layer.

20. The electronic system of claim 19, wherein:
the third source layer includes an inner sidewall directly contacting the data storage layer;
the second source layer includes an inner sidewall connecting the surface of the second source layer to a bottom surface of the second source layer; and
the inner sidewall of the second source layer directly contacts the channel layer.
